(19) United States
(12) Patent Application Publication
(10) Pub. No.: US 2025/0048575 A1
(43) Pub. Date: Feb. 6, 2025

(54) DISPLAY ASSEMBLY AND ELECTRONIC DEVICE COMPRISING DISPLAY ASSEMBLY

(71) Applicant: SAMSUNG ELECTRONICS CO., LTD., Suwon-si (KR)

(72) Inventors: Sungjin CHO, Suwon-si (KR); Jungho LEE, Suwon-si (KR); Jongwoo MOON, Suwon-si (KR); Chungwan CHU, Suwon-si (KR); Hosoon LEE, Suwon-si (KR); Jinwan AN, Suwon-si (KR)

(73) Assignee: SAMSUNG ELECTRONICS CO., LTD., Suwon-si (KR)

(21) Appl. No.: 18/926,969

(22) Filed: Oct. 25, 2024

Related U.S. Application Data
(63) Continuation of application No. PCT/KR2023/003174, filed on Mar. 8, 2023.

(30) Foreign Application Priority Data
Apr. 28, 2022 (KR) 10-2022-0052493
Jun. 21, 2022 (KR) 10-2022-0075863

(51) Int. Cl. H05K 5/03; H05K 5/02

(52) U.S. Cl. CPC H05K 5/03; H05K 5/0217

(57) ABSTRACT

An electronic device includes: a housing including a first housing, and a second housing connected to the first housing and configured to be movable with respect to the first housing; and a display assembly including a flat area connected to the housing, and a deformable area extending from the flat area and configured to be at least partially folded or rolled based on a movement relative to the housing, where the display assembly includes: a protective layer for protecting the display assembly from an external impact to the electronic device, the protective layer including a polymer film; a display panel configured to output an image; a glass disposed on the display panel; and an adhesive layer disposed between the glass and the polymer film, where a first area of the polymer film positioned in the flat area has a first thickness.

### CROSS-REFERENCE TO RELATED APPLICATION(S)

This application is a continuation of International Application No. PCT/KR2023/003174, filed on Mar. 8, 2023, in the Korean Intellectual Property Receiving Office, which is based on and claims priority to Korean Patent Applications No. 10-2022-0052493, filed on Apr. 28, 2022 and No. 10-2022-0075863, filed on Jun. 21, 2022, in the Korean Intellectual Property Office, the disclosures of which are incorporated by reference herein in their entireties.

### BACKGROUND

### 1. Field

The disclosure relates to a display assembly and an electronic device including the display assembly.

### 2. Description of Related Art

With the development of information and communication technology and semiconductor technology, various functions are packed in one portable electronic device. For example, an electronic device may implement not only communication functions but also entertainment functions, such as playing games, multimedia functions, such as playing music and videos, communication and security functions for mobile banking, and scheduling and e-wallet functions. These electronic devices have been downsized to be conveniently carried by users.

As mobile communication services extend up to multimedia service sectors, electronic devices require a larger display to allow users satisfactory use of multimedia services as well as voice call or text messaging services. However, the display size of the electronic device may be in a trade-off relationship with downsizing the electronic device.

### SUMMARY

An electronic device (e.g., a portable terminal) may include a display with a flat surface or both a flat and curved surface. An electronic device including a display may have a limitation in realizing a screen larger than the size of the electronic device due to the fixed display structure. Accordingly, research has been conducted on electronic devices including a foldable or rollable display. a

The foldable or rollable display may include a thin glass for deformation of the display shape and a polymer film for reducing damage to the glass. When relatively thin glass and polymer film are used, durability of the display may be reduced. However, as the thickness of the polymer film of the display increases, the repulsive force of the display increases, so that the force required for folding or closing the electronic device increases, and user convenience may be reduced.

According to various embodiments of the disclosure, there may be provided an electronic device including a display assembly which may maintain durability while reducing the repulsive force and driving resistance of the display.

The disclosure is not limited to the foregoing embodiments but various modifications or changes may rather be made thereto without departing from the spirit and scope of the disclosure.

According to an aspect of the disclosure, an electronic device may include: a housing including a first housing, and a second housing connected to the first housing and configured to be movable with respect to the first housing; and a display assembly including a flat area connected to the housing, and a deformable area extending from the flat area and configured to be at least partially folded or rolled based on a movement relative to the housing, where the display assembly includes: a protective layer for protecting the display assembly from an external impact to the electronic device, the protective layer including a polymer film; a display panel configured to output an image; a glass disposed on the display panel; and an adhesive layer disposed between the glass and the polymer film, where a first area of the polymer film positioned in the flat area has a first thickness, and a second area of the polymer film positioned in the deformable area has a second thickness smaller than the first thickness, and where a third area of the adhesive layer positioned in the flat area has a third thickness, and a fourth area of the adhesive layer positioned in the deformable area has a fourth thickness greater than the third thickness.

A fifth area of the glass positioned in the flat area may have a fifth thickness, and a sixth area of the glass positioned in the deformable area may have a sixth thickness smaller than the fifth thickness.

The protective layer may further include a coating layer disposed on the polymer film.

The adhesive layer may include a second adhesive layer disposed on the glass, and a first adhesive layer spaced apart from the second adhesive layer, where the polymer film includes a second polymer film disposed between the first adhesive layer and the second adhesive layer, and a first polymer film disposed on the first adhesive layer.

The second polymer film may include a 1-2th area positioned in the flat area, and a 2-2th area positioned in the deformable area and thinner than the 1-2th area, where the first adhesive layer includes a 3-1th area positioned between the first polymer film and the 1-2th area, and a 4-1th area positioned between the first polymer film and the 2-2th area and thicker than the 3-1th area, and where the second adhesive layer includes a 3-2th area positioned between the glass and the 1-2th area, and a 4-2th area positioned between the first polymer film and the 2-2th area and thicker than the 3-2th area.

The first polymer film may include a 1-1th area positioned in the flat area, and a 2-1th area positioned in the deformable area and thinner than the 1-1th area, where the second polymer film includes a 1-2th area positioned in the flat area, and a 2-2th area positioned in the deformable area and thinner than the 1-2th area, and where the first adhesive layer includes a 3-1th area positioned between the 1-1th area and the 1-2th area, and a 4-1th area positioned between the first polymer film and the 2-2th area and thicker than the 3-1th area.

The adhesive layer may include at least one of an optically clear resin (OCR) or an optically clear adhesive (OCA).

The second thickness may be from 10% to 90% of the first thickness.

A sum of a thickness of the protective layer, a thickness of the adhesive layer, and a thickness of the glass may be substantially uniform among the flat area and the deformable area.

The first area may include a first surface facing the adhesive layer, where the second area includes a second surface facing the adhesive layer, and a third surface extending from the first surface to the second surface, and where a first angle between the first surface and the third surface is at least 10 degrees and less than 30 degrees.

The electronic device of claim 1, wherein the polymer film includes a curved portion positioned between the first area and the second area and having a radial curvature of at least 0.05R.

The electronic device may further include a hinge connected to the first housing and the second housing, where the flat area includes a first flat display area positioned in the first housing and a second flat display area positioned in the second housing, and where the deformable area includes a folding area positioned between the first flat display area and the second flat display area.

The display assembly may further include a multi-bar structure supporting the display panel, where the deformable area extends from the flat area, and is at least partially connected to the multi-bar structure.

The electronic device may further include: a driving motor disposed in the housing and configured to generate a driving force for a slide movement of the housing; and a gear assembly configured to move the first housing with respect to the second housing based on the driving force.

According to an aspect of the disclosure, an electronic device may include: a housing including a first housing, and a second housing connected to the first housing and configured to be movable with respect to the first housing; and a display assembly including a flat area connected to the first housing, and a deformable area extending from the flat area and configured to be at least partially folded or rolled based on a movement relative to the housing, where the display assembly includes: a protective layer for protecting the display assembly from an external impact of the electronic device and including a polymer film; a display panel configured to output an image; a glass disposed on the display panel; and an adhesive layer disposed between the glass and the polymer film, where the polymer film includes a first film area facing outward from the display assembly, a second film area positioned in the flat area and having a first hardness, and a third film area positioned in the deformable area and having a second hardness lower than the first hardness.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram illustrating an electronic device in a network environment according to various embodiments of the disclosure;

FIG. 2 is a view illustrating an unfolded state of an electronic device according to an embodiment of the disclosure;

FIG. 3 is a view illustrating a folded state of an electronic device according to an embodiment of the disclosure;

FIG. 4 is an exploded perspective view illustrating an electronic device according to an embodiment of the disclosure;

FIG. 5 is a cross-sectional view illustrating a display in an unfolded state according to an embodiment of the disclosure;

FIG. 6 is a cross-sectional view illustrating a display in a folded state according to an embodiment of the disclosure;

FIG. 7 is a cross-sectional view illustrating a display assembly including a glass and a display panel according to an embodiment of the disclosure;

FIG. 8A, FIG. 8B, and FIG. 8C are cross-sectional views illustrating a display assembly including a polymer film and an adhesive layer according to various embodiments of the disclosure;

FIG. 9A and FIG. 9B are cross-sectional views illustrating a display assembly including a plurality of polymer films and a plurality of adhesive layers according to various embodiments of the disclosure;

FIG. 10A and FIG. 10B are cross-sectional views illustrating a display assembly including a polymer film having different hardness for each portion according to various embodiments of the disclosure;

FIG. 11 is a view illustrating an electronic device in a closed state according to an embodiment of the disclosure;

FIG. 12 is a view illustrating an electronic device in an open state according to an embodiment of the disclosure;

FIG. 13 is an exploded perspective view illustrating an electronic device according to an embodiment of the disclosure;

FIG. 14 is a cross-sectional view illustrating a display assembly in a closed state according to an embodiment of the disclosure; and

FIG. 15 is a cross-sectional view illustrating a display assembly in an open state according to an embodiment of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

It will be understood that the terms “includes,” “comprises,” “has,” “having,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

It will be understood that the terms “first”, “second”, or the like, may be used to distinguish one component from another, and should not be construed to limit the corresponding component in other aspects (e.g., importance or order). Similarly, in the following description, it will be understood that the terms 1-1th area, 1-2th area, and the like, are used to distinguish one component from another, and should not be construed to limit the corresponding component in other aspects.

An expression that one component is “connected”, “coupled”, “supported”, or “in contact” with another component includes a case in which the components are directly “connected”, “coupled”, “supported”, or “in contact” with each other and a case in which the components are indirectly “connected”, “coupled”, “supported”, or “in contact” with each other through a third component.

As used herein, each of the expressions “A or B,” “at least one of A and B,” “at least one of A or B,” “A, B, or C,” “at least one of A, B, and C,” and “at least one of A, B, or C,” may include one or all possible combinations of the items listed together with a corresponding expression among the expressions.

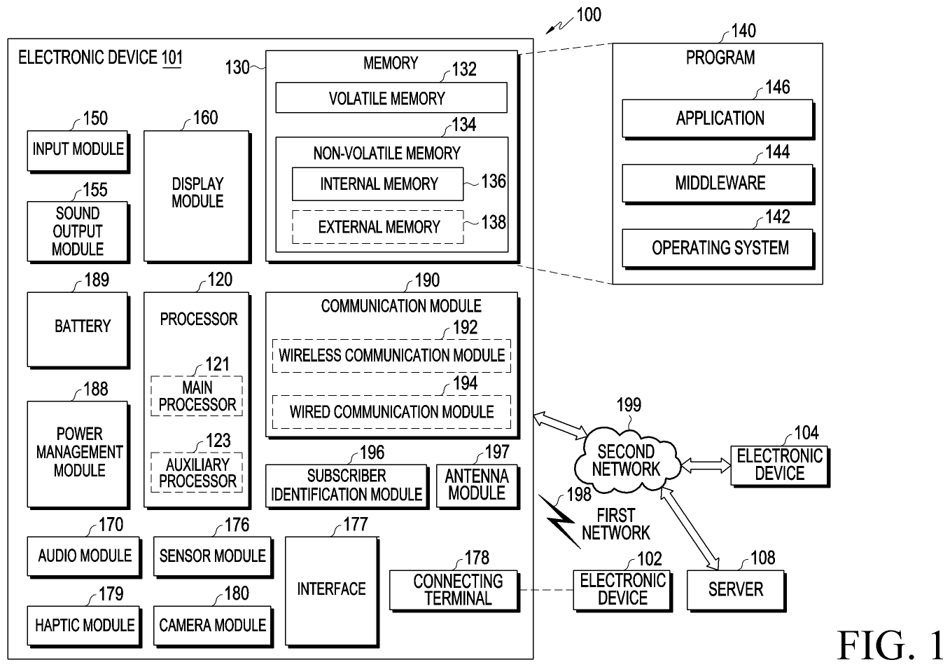

FIG. 1 is a block diagram illustrating an electronic device in a network environment according to various embodiments of the disclosure;

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module may include an antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

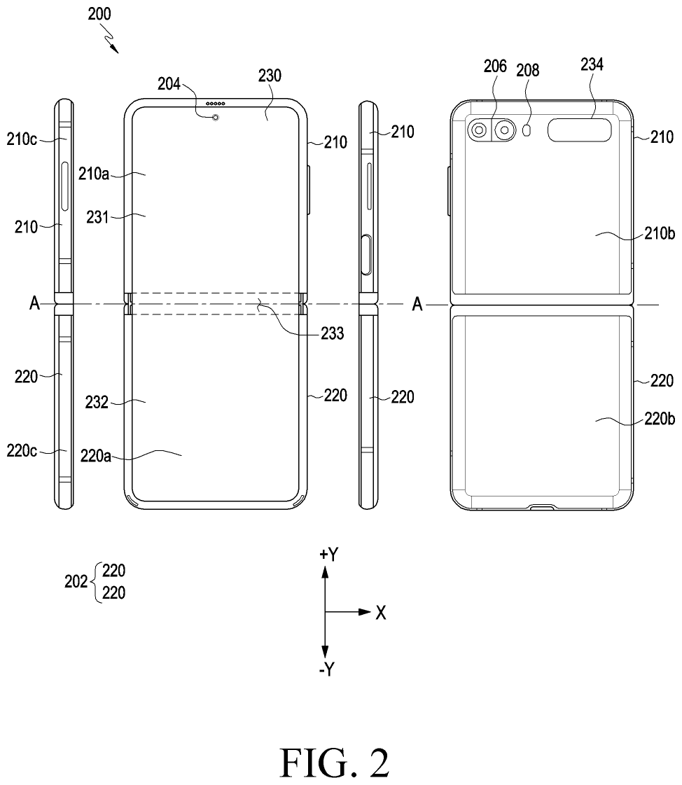

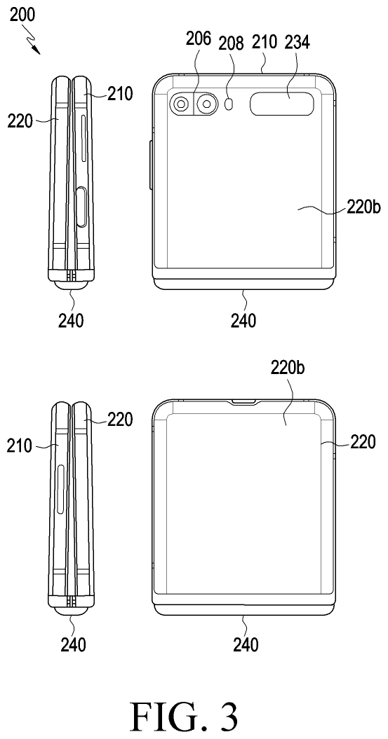

FIG. 2 is a view illustrating an unfolded state of an electronic device according to various embodiments of the disclosure. FIG. 3 is a view illustrating a folded state of an electronic device according to various embodiments of the disclosure. The configuration of the electronic device 200 of FIGS. 2 and 3 may be identical in whole or part to the configuration of the electronic device 101 of FIG. 1.

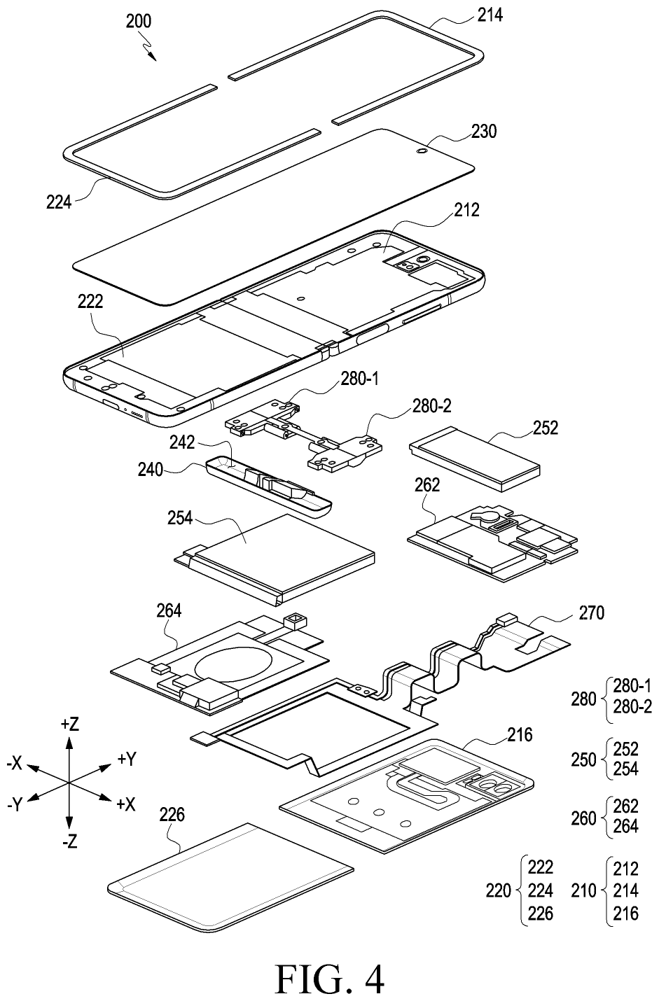

Referring to FIGS. 2 and 3, an electronic device 200 may include a housing 202 for receiving a component (e.g., the hinge structure 280 of FIG. 4) of the electronic device 200 and a flexible display or foldable display 230 (hereinafter, display 230) disposed in the space formed by the housing 202. According to an embodiment, the housing 202 may be referred to as a foldable housing. According to an embodiment, the housing 202 may include a first housing 210 and a second housing 220 configured to be movable relative to the first housing 210. For example, the second housing 220 may be rotated with respect to the first housing 210.

According to various embodiments, the first housing 210 and/or the second housing 220 may form a portion of the exterior of the electronic device 200. According to an embodiment, the surface where the display 230 is visually exposed is defined as a front surface (e.g., a first front surface 210a and a second front surface 220a) of the electronic device 200 and/or housing 202. A surface opposite to the front surface is defined as a rear surface (e.g., the first rear surface 210b and the second rear surface 220b) of the electronic device 200. A surface surrounding at least a portion of the space between the front surface and the rear surface is defined as a side surface (e.g., the first side surface 210c and the second side surface 220c) of the electronic device 200.

According to various embodiments, the first housing 210 may be rotatably connected to the second housing 220 by a hinge structure (e.g., the hinge structure 280 of FIG. 3). For example, the first housing 210 and the second housing 220 may be connected to each other to be rotatable about the hinge structure 280. Thus, the electronic device 200 may turn into a folded state (e.g., FIG. 3) or unfolded state (e.g., FIG. 2). In the folded state of the electronic device 200, the first front surface 210a may face the second front surface 220a and, in the unfolded state, the direction in which the first front surface 210a faces may be the same as the direction in which the second front surface 220a faces. For example, in the unfolded state, the first front surface 210a may be positioned on substantially the same plane as the second front surface 220a.

According to various embodiments, the first housing 210 and the second housing 220 are disposed on both sides of the folding axis A and be overall symmetrical in shape with respect to the folding axis A. The angle between the first housing 210 and the second housing 220 may be changed depending on whether the electronic device 200 is in the unfolded state, the folded state, or an intermediate state between the unfolded state and the folded state.

According to various embodiments, the electronic device 200 may include a hinge cover 240. At least a portion of the hinge cover 240 may be disposed between the first housing 210 and the second housing 220. According to an embodiment, the hinge cover 240 may be hidden by a portion of the first housing 210 and second housing 220 or be exposed to the outside depending on the state of the electronic device 200. According to an embodiment, the hinge cover 240 may protect the hinge structure (e.g., the hinge structure 280 of FIG. 4) from an external impact of the electronic device 200. According to an embodiment, the hinge cover 240 may be interpreted as a hinge housing for protecting the hinge structure 280.

According to an embodiment, as shown in FIG. 2, in the unfolded state of the electronic device 200, the hinge cover 240 may be hidden, and thus not exposed, by the first housing 210 and the second housing 220. As another example, as shown in FIG. 3, in the folded state (e.g., a fully folded state) of the electronic device 200, the hinge cover 240 may be exposed to the outside between the first housing 210 and the second housing 220. As another example, in an intermediate state in which the first housing 210 and the second housing 220 are folded with a certain angle, the hinge cover 240 may be partially exposed to the outside between the first housing 210 and the second housing 220. However, in this case, the exposed area may be smaller than that in the completely folded state. In an embodiment, the hinge cover 240 may include a curved surface.

According to various embodiments, the display 230 (e.g., the display module 160 of FIG. 1) may visually provide information to the outside (e.g., a user) of the electronic device 200. The display 230 may include, for example, a hologram device, or a projector and control circuitry to control a corresponding one of the display, hologram device, and projector. According to an embodiment, the display 230 may include a touch sensor configured to detect a touch, or a pressure sensor configured to measure the intensity of a force generated by the touch. According to an embodiment, the display 230 may be referred to as a display assembly.

According to various embodiments, the display 230 may mean a display at least a portion of which may be transformed into a flat or curved surface. For example, the display 230 may be formed to be transformable in response to the motion of the second housing 220 relative to the first housing 210. According to an embodiment, the display 230 may include a folding area 233, a first flat display area 231 disposed on one side of the folding area 233 (e.g., the upper (+Y) direction), and a second flat display area 232 disposed on the opposite side of the folding area 233 (e.g., lower (−Y) direction). According to an embodiment, the folding area 233 may be formed over the hinge structure (e.g., the hinge structure 280 of FIG. 4). For example, at least a portion of the folding area 233 may face the hinge structure 280. According to an embodiment, the first flat display area 231 may be disposed on the first housing 210, and the second flat display area 232 may be disposed on the second housing 220. According to an embodiment, the display 230 may be received in the first housing 210 and the second housing 220. According to an embodiment, the first flat display area 231 and the second flat display area 232 may be referred to as a flat area. The first flat display area 231 and the second flat display area 232 may be connected to the housing 202. According to an embodiment, the folding area 233 may be referred to as a deformable area configured to be at least partially folded based on a relative movement of the housing 202.

However, the segmentation of the display 230 as shown in FIG. 2 is merely an example, and the display 230 may be divided into a plurality of (e.g., four or more, or two) areas depending on the structure or function of the display 200.

Further, in the embodiment illustrated in FIG. 2, the area of the display 230 may be segmented by the folding area 233 or folding axis (axis A) extending in parallel with the X axis but, in another embodiment, the display 230 may also be segmented with respect to other folding area (e.g., a folding area parallel with the Y axis) or other folding axis (e.g., a folding axis parallel with the Y axis). According to an embodiment, the display 230 may be coupled with or disposed adjacent to a touch detection circuit, a pressure sensor capable of measuring the strength (pressure) of touches, and/or a digitizer for detecting a magnetic field-type stylus pen.

According to various embodiments, the electronic device 200 may include a rear display 234. The rear display 234 may be disposed to face in a different direction from the display 230. For example, the display 230 may be visually exposed through the front surface (e.g., the first front surface 210a and/or the second front surface 220a) of the electronic device 200, and the rear display 234 may be visually exposed through the rear surface (e.g., the first rear surface 210b) of the electronic device 200.

According to various embodiments, the electronic device 200 may include at least one camera module 204 and 206 and a flash 208. According to an embodiment, the electronic device 200 may include a front camera module 204 exposed through the front surface (e.g., the first front surface 210a) and/or a rear camera module 206 exposed through the rear surface (e.g., the first rear surface 220b). The camera modules 204 and 206 may include one or more lenses, an image sensor, a flash, and/or an image signal processor. The flash 208 may include a light emitting diode (LED) or a xenon lamp. In an embodiment, two or more lenses (infrared camera, wide-angle and telephoto lens) and image sensors may be disposed on one surface of the electronic device 200. The configuration of the front camera module 204 and/or rear camera module 206 may be identical in whole or part to the configuration of the camera module 180 of FIG. 1.

FIG. 4 is an exploded perspective view illustrating an electronic device according to various embodiments of the disclosure;

Referring to FIG. 4, an electronic device 201 may include a first housing 210, a second housing 220, a display 230, a hinge cover 240, a battery 250, a printed circuit board 260, a flexible printed circuit board 270, and a hinge structure 280. The configuration of the first housing 210, the second housing 220, the display 230, and the hinge cover 240 of FIG. 4 may be identical in whole or part to the configuration of the first housing 210, the second housing 220, the display 230, and the hinge cover 240 of FIGS. 2 and/or 3.

According to various embodiments, the electronic device 200 may include a first supporting member 212 or a second supporting member 222. For example, the first housing 210 may include a first supporting member 212, and the second housing 220 may include a second supporting member 222. According to an embodiment, the first supporting member 212 and/or the second supporting member 222 may support components (e.g., the display 230, the battery 250, and the printed circuit board 260) of the electronic device 200.

According to an embodiment, the first supporting member 212 and/or the second supporting member 222 may be formed of a metal material and/or a non-metal (e.g., polymer) material. According to an embodiment, the first supporting member 212 may be disposed between the display 230 and the battery 250. For example, the display 230 may be coupled to one surface of the first supporting member 212, and the battery 250 and the printed circuit board 260 may be disposed on the other surface.

According to various embodiments, the electronic device 200 may include a first protection member 214 or a second protection member 224. For example, the first housing 210 may include a first protection member 214, and the second housing 220 may include a second protection member 224. According to an embodiment, the protection members 214 and 224 may protect the display 230 from external impact. For example, the first protection member 214 may surround at least a portion of a portion (e.g., the first flat display area 231 of FIG. 1) of the display 230, and the second protection member 224 may surround at least a portion of another portion (e.g., the second flat display area 232 of FIG. 1) of the display 230. According to an embodiment, the first protection member 214 may be referred to as a first deco member, and the second protection member 214 may be referred to as a second deco member.

According to various embodiments, the housings 210 and 220 may include a first rear plate 216 and a second rear plate 226. For example, the first housing 210 may include a first rear plate 216 connected to the first supporting member 212, and the second housing 220 may include a second rear plate 226 connected to the second supporting member 222. According to an embodiment, the rear plates 216 and 226 may form at least a portion of the exterior of the electronic device 200. For example, the first rear plate 216 may form a first rear surface (e.g., the first rear surface 210b of FIG. 1), and the second rear plate 226 may form a second rear surface (e.g., the second rear surface 220b of FIG. 1). According to an embodiment, the first battery 252 and the first printed circuit board 262 may be disposed between the first supporting member 212 and the first rear plate 216. The second battery 254 and the second printed circuit board 264 may be disposed between the second supporting member 222 and the second rear plate 226.

According to various embodiments, the hinge cover 240 may receive at least a portion of the hinge structure 280. For example, the hinge cover 240 may include a receiving recess 242 for receiving the hinge structure 280. According to an embodiment, the hinge cover 240 may be coupled to the hinge structure 280. According to an embodiment, in the unfolded state of the electronic device 200, at least a portion of the hinge cover 240 may be positioned between the hinge structure 280 and the housings 210 and 220.

According to various embodiments, the battery 250 may be a device for supplying power to at least one component of the electronic device 200. The battery 189 may include a primary cell which is not rechargeable, a secondary cell which is rechargeable, or a fuel cell. The battery 250 may be integrally or detachably disposed inside the electronic device 200. According to an embodiment, the battery 250 may include a first battery 252 disposed in the first housing 210 and a second battery 254 disposed in the second housing 220. For example, the first battery 252 may be disposed on the first supporting member 212. The second battery 254 may be disposed on the second supporting member 222.

According to various embodiments, a processor (e.g., the processor 220 of FIG. 1), a memory (e.g., the memory 230 of FIG. 1), and/or an interface (e.g., the interface 277 of FIG. 1) may be mounted on the printed circuit board 260. According to an embodiment, the printed circuit board 260 may include a first printed circuit board 262 disposed in the first housing 210 and a second printed circuit board 264 disposed in the second housing 220.

According to various embodiments, the flexible printed circuit board 270 may electrically connect a component (e.g., first printed circuit board 262) positioned in the first housing 210 with a component (e.g., first printed circuit board 262) positioned in the second housing 220. According to an embodiment, at least a portion of the flexible printed circuit board 270 may cross the hinge cover 240 and/or the hinge structure 280. For example, a portion of the flexible printed circuit board 270 may be disposed in the first housing 210, and another portion thereof may be disposed in the second housing 220.

According to various embodiments, the hinge structure 280 may be connected to the first housing 210 and the second housing 220. According to an embodiment, the first housing 210 may rotate about the second housing 220 by the hinge structure 280. According to an embodiment, the hinge structure 280 may rotatably connect the first housing 210 and the second housing 220 from a folded state (e.g., FIG. 3) to an unfolded state (e.g., FIG. 2). According to an embodiment, at least a portion of the hinge structure 280 may be positioned under the folding area (e.g., the folding area 233 of FIG. 3). For example, when the electronic device 200 is viewed from above (e.g., the +Z direction), at least a portion of the hinge structure 280 may overlap the folding area 233.

According to an embodiment, the hinge structure 280 may include a plurality of hinge structures 280-1 and 280-2 disposed in parallel. For example, the hinge structure 280 may include a first hinge structure 280-1 and a second hinge structure 280-2 spaced apart from the first hinge structure 280-1. According to an embodiment, the first hinge structure 280-1 may be symmetrical with the second hinge structure 280-2 with respect to the length direction (e.g., the Y-axis direction) of the electronic device 200.

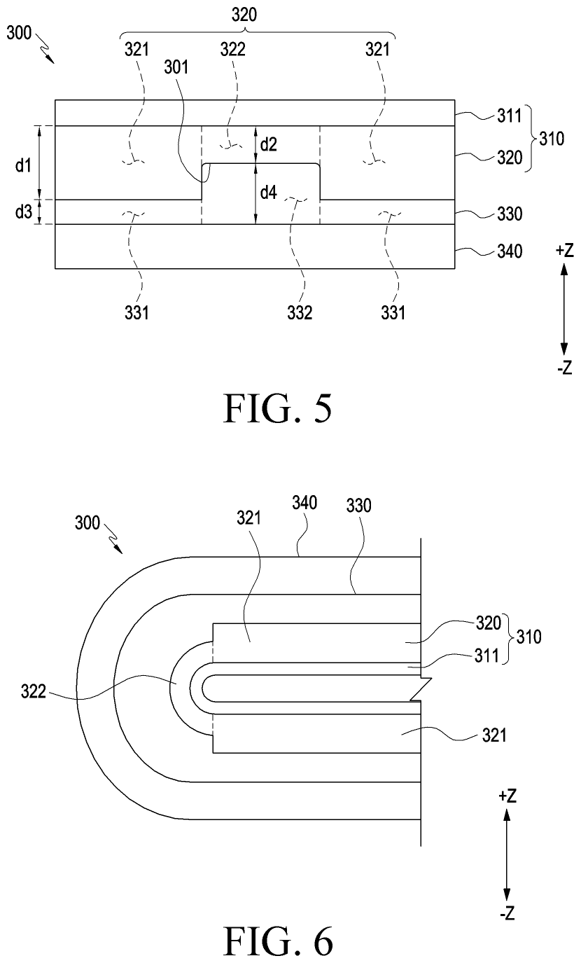

FIG. 5 is a cross-sectional view illustrating a display in an unfolded state according to an embodiment of the disclosure. FIG. 6 is a cross-sectional view illustrating a display in a folded state according to an embodiment of the disclosure. For example, FIG. 5 is a cross-sectional view of a portion of the display 230 of FIG. 2. FIG. 6 is a cross-sectional view of a portion of the display 230 of FIG. 3.

Referring to FIGS. 5 and 6, the display assembly 300 may include a protective layer 310, an adhesive layer 330, and a glass 340. The configuration of the display assembly 300 of FIG. 5 and/or FIG. 6 may be identical in whole or part to the configuration of the display 230 of FIG. 4.

According to various embodiments, the protective layer 310 may protect the display assembly 300 from an external impact. For example, the protective layer 310 may include a coating layer 311 for reducing damage (e.g., scratches) of the display assembly 300 and a polymer film 320 for reducing damage (e.g., breaks) to the glass 340. For example, even if the thickness of the glass 340 is reduced due to the polymer film 320, the strength of the display assembly 300 may be maintained.

According to various embodiments, the coating layer 311 may be positioned at the outermost portion of the display assembly 300. For example, the coating layer 311 may be disposed on the polymer film 320. According to an embodiment, the coating layer 311 may be a hard coating layer applied on the polymer film 320 to enhance the strength of the display assembly 300.

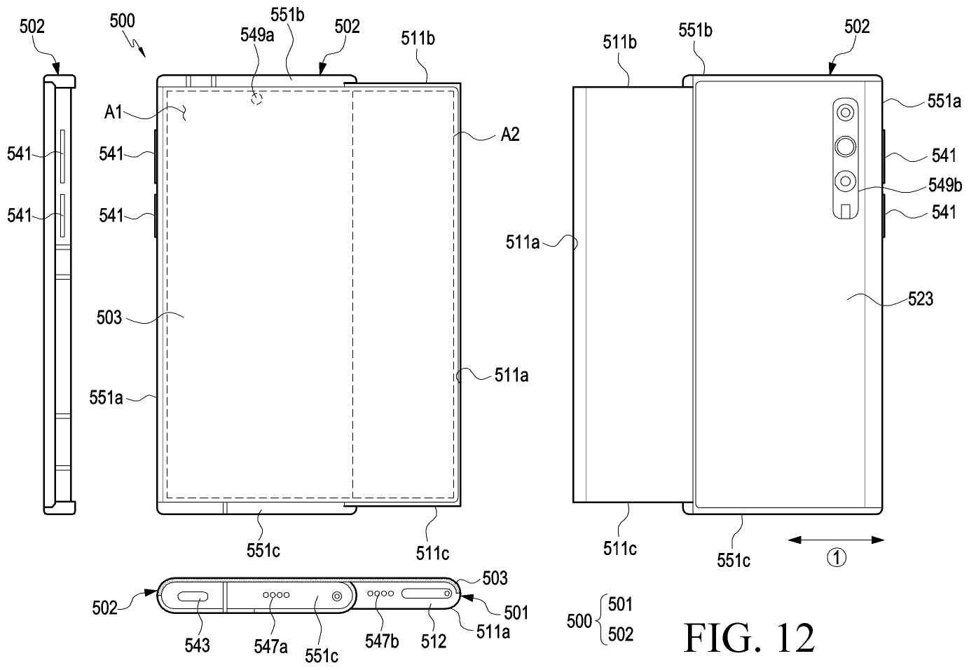

According to various embodiments, at least a portion of the display assembly 300 may be bent. For example, the deformable area (e.g., the folding area 233 of FIG. 2 or the deformable display area A2 of FIG. 12) of the display assembly 300 may be bent based on the movement of the electronic device (e.g., the electronic device 200 of FIG. 2).

According to various embodiments, the polymer film 320 may be formed to be bent based on deformation of the display assembly 300. For example, the polymer film 320 may have a different thickness for each portion. According to an embodiment, the polymer film 320 may include a first area 321 positioned in a flat area (e.g., the first flat display area 231 and/or the second flat display area 232 of FIG. 2) of a display (e.g., the display 230 of FIG. 2) and a second area 322 positioned in a deformable area (e.g., the folding area 233 of FIG. 2) of the display 230. The second thickness d2 of the second area 322 may be smaller than the first thickness d1 of the first area 321. For example, the second thickness d2 may be 10% to 90% of the first thickness d1. According to an embodiment, the first thickness d1 may be about 100 μm, and the second thickness d2 may be about 50 μm. According to an embodiment, the first thickness d1 may range from about 30 μm to 150 μm.

According to an embodiment, since the second thickness d2 of the second area 322 is formed to be smaller than the first thickness d1 of the first area 321, bending (e.g., folding) of the display assembly 300 may be enhanced. For example, the repulsive force of the second area 322 may be less than the repulsive force of the first area 321, and the repulsive force of the deformable area in which the second area 322 is positioned may be less than the repulsive force of the flat area in which the first area 321 is positioned.

According to an embodiment, the polymer film 320 may include a resin. For example, the polymer film 320 may include polyethylene terephthalate (PET), polycarbonate (PC), polymethyl methacrylate (PMMA), and/or thermoplastic polyurethane (TPU).

According to an embodiment, the polymer film 320 may include a curved portion 301 for reducing the visibility of the polymer film 320 due to the difference between the first thickness d1 of the first area 321 and the second thickness d2 of the second area 322. According to an embodiment, the curved portion 301 may be positioned between the first area 321 and the second area 322. The curved portion 301 may have a curvature of 0.05R or more.

According to various embodiments, the adhesive layer 330 may connect or adhere the protective layer 310 to the glass 340. According to an embodiment, the adhesive layer 330 may be disposed between the polymer film 320 and the glass 340. For example, the adhesive layer 330 may be coated on the glass 340 (e.g., +Z direction) in a coated liquid state and disposed on the glass 340, and the polymer film 320 may be stacked on the adhesive layer 330 in a coated liquid state (+Z direction). The adhesive layer 330 may be cured using ultraviolet curing.

According to various embodiments, the adhesive layer 330 may be formed to correspond to the shape of the polymer film 320. For example, the adhesive layer 330 may have a different thickness for each portion. According to an embodiment, the adhesive layer 330 may include a third area 331 positioned in a flat area (e.g., the first flat display area 231 and/or the second flat display area 232 of FIG. 2) of a display (e.g., the display 230 of FIG. 2) and a fourth area 332 positioned in a deformable area (e.g., the folding area 233 of FIG. 2) of the display 230. A fourth thickness d4 of the fourth area 332 may be larger than a third thickness d3 of the third area 331.

According to an embodiment, as the fourth thickness d4 of the fourth area 332 is formed to be larger than the third thickness d3 of the third area 331, the display assembly 300 may have a substantially flat shape. For example, the third thickness d3 may be 10% to 90% of the fourth thickness d4. According to an embodiment, the sum of the thicknesses of the polymer film 320 and the sum of the thicknesses of the adhesive layer 330 may be substantially uniform. For example, the sum of the first thickness d1 of the polymer film 320 and the third thickness d3 of the adhesive layer 330 may be substantially the same as the sum of the second thickness d2 of the polymer film 320 and the fourth thickness d4 of the adhesive layer 330. According to an embodiment, the adhesive layer 330 may absorb at least a portion of the impact transferred to the display assembly 300.

According to various embodiments, the modulus of the adhesive layer 330 may be set as various values. According to an embodiment, the modulus of the adhesive layer 330 may range from about 100 MPa to 500 MPa. According to another embodiment, the modulus of the adhesive layer 330 may range from about 0 MPa to about 100 MPa. The modulus may be referred to as an elastic modulus reflecting a ratio of stress and deformation.

According to various embodiments, the repulsive force of the deformable area (e.g., the folding area 233 of FIG. 2) of the display assembly 300 may be less than the repulsive force of the flat area (e.g., the first flat display area 231 and/or the second flat display area 232 of FIG. 2) of the display assembly 300. For example, when the adhesive layer 330 and the polymer film 320 have the same thickness, the repulsive force of the adhesive layer 330 may be less than the repulsive force of the polymer film 320. According to an embodiment, in the deformable area (e.g., the folding area 233 of FIG. 2) of the display assembly 300, the fourth thickness d4 of the fourth area 332 of the adhesive layer 330 may be larger than the second thickness d2 of the second area 322 of the polymer film 320. According to an embodiment, in the flat area (e.g., the first flat display area 231 and/or the second flat display area 232 of FIG. 2) of the display assembly 300, the third thickness d3 of the third area 331 of the adhesive layer 330 may be smaller than the first thickness d1 of the first area 321 of the polymer film 320.

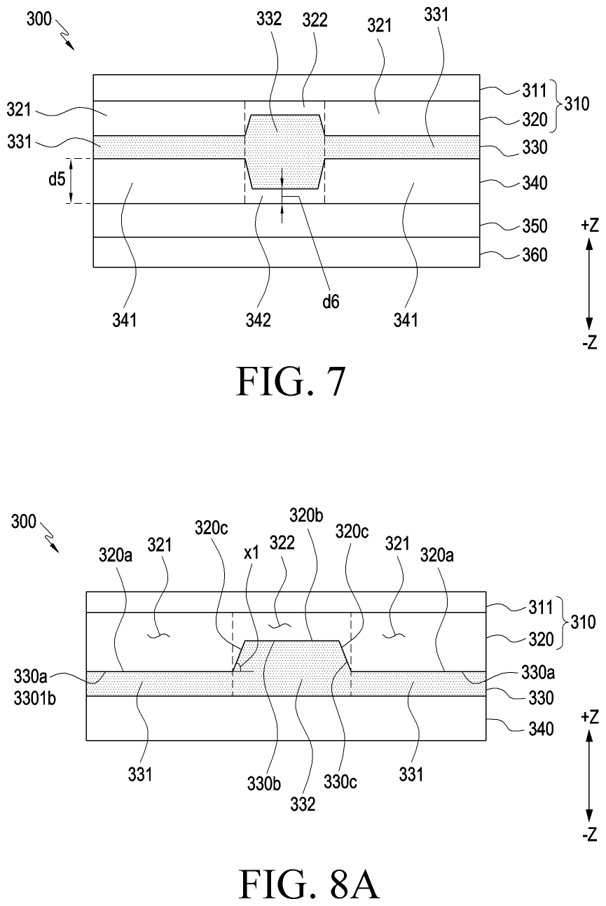

According to various embodiments, the adhesive layer 330 may transmit at least a portion of light generated from a display panel (e.g., the display panel 350 of FIG. 7). For example, the adhesive layer 330 may be substantially transparent. According to an embodiment, the adhesive layer 330 may include an optically clear resin (OCR) and/or an optically clear adhesive (OCA). According to an embodiment, the material of the adhesive layer 330 may be changed considering light transmittance and/or strength. For example, the adhesive layer 330 may include an acrylic, silicone, or urethane coating solution having substantially the same refractive index. According to an embodiment, the adhesive layer 330 may be attached to the glass 340 through ultraviolet curing.

According to various embodiments, the glass 340 may be folded together with the protective layer 310 and the adhesive layer 330. According to an embodiment, the glass 340 may be positioned under the adhesive layer 330 (e.g., in the −Z direction). According to an embodiment, the polymer film 320 may be connected to or attached to the glass 340 using the adhesive layer 330. According to an embodiment, the glass 340 may be ultra-thin glass (UTG). For example, the thickness range of the glass 340 may be about 30 μm to 50 μm.

FIG. 7 is a cross-sectional view illustrating a display assembly including a glass and a display panel according to an embodiment of the disclosure.

Referring to FIG. 7, a display assembly 300 may include a protective layer 310 including a coating layer 311 and a polymer film 320, an adhesive layer 330, a glass 340, a display panel 350, and/or a display supporting member 360. The configuration of the coating layer 311, the polymer film 320, the protective layer 310, the adhesive layer 330, and the glass 340 of FIG. 7 may be identical in whole or part to the configuration of the coating layer 311, the polymer film 320, the protective layer 310, the adhesive layer 330, and the glass 340 of FIG. 5.

According to various embodiments, the glass 340 may protect the display panel 350. For example, the glass 340 may be disposed on the display panel 350. According to an embodiment, the glass 340 may be positioned between the adhesive layer 330 and the display panel 350.

According to various embodiments, the glass 340 may be formed to be bent based on deformation of the display assembly 300. For example, the glass 340 may have a different thickness for each portion. According to an embodiment, the glass 340 may include a fifth area 341 positioned in a flat area (e.g., the first flat display area 231 and/or the second flat display area 232 of FIG. 2) of the display (e.g., the display 230 of FIG. 2) and a sixth area 342 positioned in a deformable area (e.g., the folding area 233 of FIG. 2) of the display 230. A sixth thickness d6 of the sixth area 342 may be smaller than a fifth thickness d5 of the fifth area 341. For example, the sixth thickness d6 may be 10% to 90% of the fifth thickness d5. According to an embodiment, the glass 340 may be designed to have various thicknesses. For example, the fifth thickness d5 may be about 50 μm, and the sixth thickness d6 may be about 30 μm. As another example, the fifth thickness d5 may be about 80 μm, and the sixth thickness d6 may be about 40 μm.

According to various embodiments, the adhesive layer 330 may be formed to correspond to the shapes of the polymer film 320 and the glass 340. For example, the adhesive layer 330 applied between the polymer film 320 and the glass 340 in the coated liquid state may be cured using ultraviolet rays.

According to various embodiments, the display panel 350 may be disposed under the glass 340. The display panel 350 may visually provide information to the outside of an electronic device (e.g., the electronic device 200 of FIG. 2). The configuration of the display panel 350 may be identical in whole or part to the configuration of the display panel 350 of FIG. 1.

According to various embodiments, the display supporting member 360 may support the display panel 350. For example, the display supporting member 360 may be a metal member positioned under (in the −Z direction) the display panel 350. According to an embodiment, the display supporting member 360 may include a plurality of through holes or patterns for bending. For example, the display supporting member 360 may include a lattice pattern.

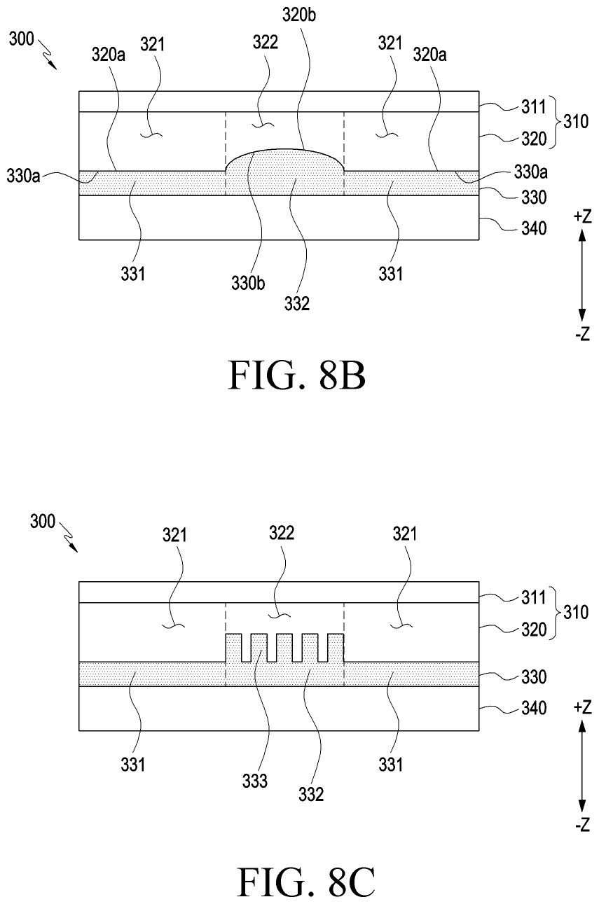

FIGS. 8A to 8C are cross-sectional views illustrating a display assembly including a polymer film and an adhesive layer according to various embodiments of the disclosure.

Referring to FIGS. 8A, 8B, and 8C, the display assembly 300 may include a protective layer 310 including a coating layer 311 and a polymer film 320, an adhesive layer 330, and a glass 340. The configuration of the protective layer 310, the adhesive layer 330, and the glass 340 of FIGS. 8A, 8B, and 8C may be identical in whole or part to the configuration of the protective layer 310, the adhesive layer 330, and the glass 340 of FIG. 5.

According to various embodiments, the polymer film 320 may be formed in various shapes. For example, if the average thickness in the thickness direction (Z-axis direction) of the first area 321 positioned in the flat area (e.g., the first flat display area 231 and/or the second flat display area 232 of FIG. 2) of the display assembly 300 is smaller than the average thickness in the thickness direction of the second area 322 positioned in the deformable area (e.g., the folding area 233 of FIG. 2), the polymer film 320 may have various shapes.

According to an embodiment (e.g., FIG. 8A), the polymer film 320 may have a substantially trapezoidal groove. For example, the first area 321 of the polymer film 320 may include a first surface 320a facing the adhesive layer 330, and the second area 322 may include a second surface 320b facing the adhesive layer 330 and a third surface 320c extending from the first surface 320a to the second surface 320b. According to an embodiment, the third surface 320c may be inclined with respect to the first surface 320a and/or the second surface 320b. For example, the range of the first angle x1 between the first surface 320a and the third surface 320c may be 10 to 30. According to an embodiment, the adhesive layer 330 may have a substantially trapezoidal protrusion to correspond to the shape of the polymer film 320. For example, the third area 331 of the adhesive layer 330 may include a fourth surface 330a in contact with the first surface 320a, and the fourth area 332 of the adhesive layer 330 may include a fifth surface 330b in contact with the second surface 320b and the third surface 320c.

According to an embodiment (e.g., FIG. 8B), the polymer film 320 may have a substantially circular groove. For example, the first area 321 of the polymer film 320 may include a first surface 320a facing the third area 331 of the adhesive layer 330, and the second area 322 may include a second surface 320b facing the fourth area 324 of the adhesive layer 330 and bent. For example, the second surface 320b may be referred to as a surface of a groove formed in the first surface 320a. According to an embodiment, the adhesive layer 330 may have a substantially circular protrusion to correspond to the shape of the polymer film 320. For example, the third area 331 of the adhesive layer 330 may include a fourth surface 330a in contact with the first surface 320a, and the fourth area 332 of the adhesive layer 330 may include a fifth surface 330b surrounded by the second surface 320b.

According to an embodiment (e.g., FIG. 8C), the polymer film 320 may have a plurality of grooves. For example, the first area 321 of the polymer film 320 may include a first surface 320a in contact with the third area 331 of the adhesive layer 330, and the second area 322 may include a plurality of grooves. According to an embodiment, the adhesive layer 330 may include a plurality of protrusions 333 positioned in the plurality of grooves to correspond to the shape of the polymer film 320. The plurality of protrusions 333 may be positioned in the second area 322.

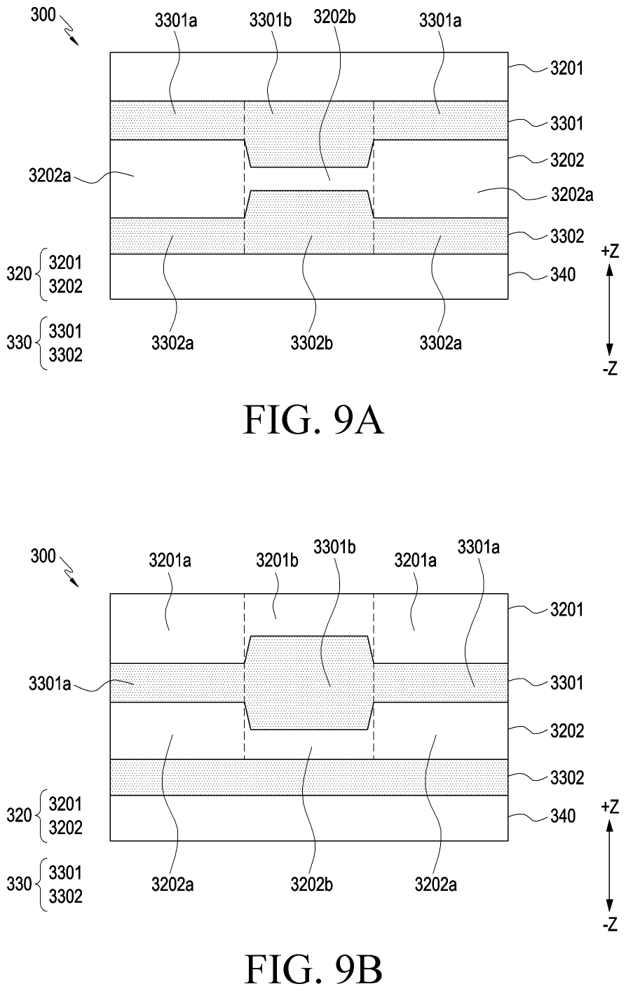

FIGS. 9A and 9B are cross-sectional views illustrating a display assembly including a plurality of polymer films and a plurality of adhesive layers according to various embodiments of the disclosure.

Referring to FIGS. 9A and 9B, the display assembly 300 may include a polymer film 320, an adhesive layer 330, and a glass 340. The configuration of the polymer film 320, the adhesive layer 330, and the glass 340 of FIGS. 9A and 9B may be identical in whole or part to the configuration of the polymer film 320, the adhesive layer 330, and the glass 340 of FIG. 5.

According to various embodiments, the polymer film 320 may include a plurality of polymer films 3201 and 3202. For example, the polymer film 320 may include a first polymer film 3201 and a second polymer film 3202 spaced apart from the first polymer film 3201. According to an embodiment, the first polymer film 3201 may be positioned to face outward of the display assembly 300. For example, the first polymer film 3201 may be disposed on the first adhesive layer 3301. According to an embodiment, the second polymer film 3202 may be disposed between the first adhesive layer 3301 and the second adhesive layer 3302. According to an embodiment, the material of the first polymer film 3201 and the material of the second polymer film 3202 may be different. For example, the first polymer film 3201 may include polyethylene terephthalate (PET) and/or polycarbonate (PC). The second polymer film 3202 may include thermoplastic polyurethane (TPU). According to an embodiment, as the polymer film 320 includes the plurality of polymer films 3201 and 3202, the thickness of one polymer film (e.g., the first polymer film 3201 and/or the second polymer film 3202) may be reduced. As the thickness of one polymer film 320 is reduced, the repulsive force of the display assembly 300 may be reduced.

According to various embodiments, the adhesive layer 330 may include a plurality of adhesive layers 3301 and 3302. For example, the adhesive layer 330 may include a first adhesive layer 3301 and a second adhesive layer 3302 spaced apart from the first adhesive layer 3301. For example, the adhesive layer 330 may include a first adhesive layer 3301 and a second adhesive layer 3302 spaced apart from the first adhesive layer 3301. According to an embodiment, the first adhesive layer 3301 may be disposed between the first polymer film 3201 and the second polymer film 3202. The second adhesive layer 3302 may be disposed between the second polymer film 3202 and the glass 340.

According to various embodiments, the first polymer film 3201 and/or the second polymer film 3202 may be formed in a shape to be bent based on deformation of the display assembly 300.

Referring to FIG. 9A, the first polymer film 3201 may have a substantially uniform thickness, and the second polymer film 3202 may have a different thickness for each portion. For example, the second polymer film 3202 may include a 1-2th area 3202a positioned in a flat area (e.g., the first flat display area 231 and/or the second flat display area 232 of FIG. 2) of a display (e.g., the display 230 of FIG. 2) and a 2-2th area 3202b positioned in a deformable area (e.g., the folding area 233 of FIG. 2) of the display 230. The thickness of the 2-2th area 3202b may be smaller than the thickness of the 1-2th area 3202a.

According to an embodiment, the first adhesive layer 3301 and the second adhesive layer 3302 may have shapes corresponding to the shape of the second polymer film 3202. For example, the first adhesive layer 3301 and the second adhesive layer 3302 may have a different thickness for each portion. For example, referring to FIG. 9A, the first adhesive layer 3301 may include a 3-1th area 3301a positioned between the first polymer film 3201 and the 1-2th area 3202a of the second polymer film 3202, and a 4-1th area 3301b positioned between the first polymer film 3201 and the 2-2th area 3202b of the second polymer film 3202. According to an embodiment, the thickness of the 3-1th area 3301a may be smaller than the thickness of the 4-1th area 3301b. For example, the second adhesive layer 3302 may include a 3-2th area 3302a positioned between the glass 340 and the 1-2th area 3202a of the second polymer film 3202, and a 4-2th area 3302b positioned between the glass 340 and the 2-2th area 3202b of the second polymer film 3202. According to an embodiment, the thickness of the 3-2th area 3302a may be smaller than the thickness of the 4-2th area 3302b.

Referring to FIG. 9B, the first polymer film 3201 and the second polymer film may have a different thickness for each portion. For example, the first polymer film 3201 may include a 1-1th area 3201a positioned in a flat area (e.g., the first flat display area 231 and/or the second flat display area 232 of FIG. 2) of a display (e.g., the display 230 of FIG. 2) and a 2-1th area 3201b positioned in a deformable area (e.g., the folding area 233 of FIG. 2) of the display 230. The thickness of the 2-1th area 3201b may be smaller than the thickness of the 1-1th area 3201a. The second polymer film 3202 may include a 1-2th area 3202a positioned in the flat area of the display (e.g., the display 230 of FIG. 2) and a 2-2th area 3202b positioned in the deformable area of the display 230. The thickness of the 2-2th area 3202b may be smaller than the thickness of the 1-2th area 3202a. According to an embodiment, the first adhesive layer 3301 may have a shape corresponding to the shape of the second polymer film 3202. For example, the first adhesive layer 3301 may have a different thickness for each portion.

For example, referring to FIG. 9B, the first adhesive layer 3301 may include a 3-1th area 3301a positioned between the 1-1th area 3201a of the first polymer film 3201 and the 1-2th area 3202a of the second polymer film 3202, and a 4-1th area 3301b positioned between the 1-2th area 3201b of the first polymer film 3201 and the 2-2th area 3202b of the second polymer film 3202. According to an embodiment (e.g., FIG. 9A and/or FIG. 9B), the thickness of the 3-1th area 3301a may be smaller than the thickness of the 4-1th area 3301b. According to an embodiment (e.g., FIG. 9A), the thickness of the 3-2th area 3302a may be smaller than the thickness of the 4-2th area 3302b. According to an embodiment (e.g., FIG. 9B), the second adhesive layer 3302 may have a substantially uniform thickness.

The polymer film 320 and the adhesive layer 330 may have various shapes. For example, in addition to the shapes illustrated in FIGS. 9 and 9B, if the sum of the thicknesses of the polymer film 320 positioned in the deformable area of the display assembly 300 is less than the sum of the thicknesses of the polymer film 320 positioned in the flat area, the polymer film 320 may be designed in various shapes.

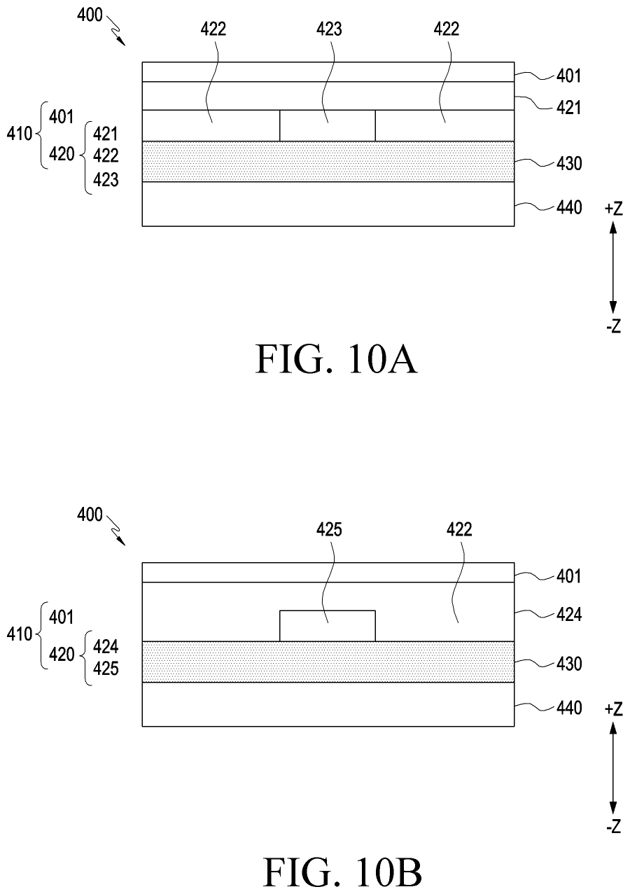

FIGS. 10A and 10B are cross-sectional views illustrating a display assembly including a polymer film having different hardness for each portion according to various embodiments of the disclosure.

Referring to FIGS. 10A and 10B, the display assembly 400 may include a protective layer 410 including a coating layer 401 and a polymer film 420, an adhesive layer 430, and a glass 440. The configuration of the coating layer 401, the protective layer 410, the polymer film 420, the adhesive layer 430, and the glass 440 of FIGS. 10A and 10B may be identical in whole or part to the configuration of the coating layer 311, the protective layer 310, the polymer film 320, the adhesive layer 330, and the glass 340 of FIG. 5.

According to various embodiments, the polymer film 420 may be formed to be bent based on deformation of the display assembly 300. For example, the polymer film 420 may have a different hardness for each portion. For example, the hardness of at least a portion of the polymer film 420 positioned in the flat area (e.g., the first flat display area 231 and/or the second flat display area 232 of FIG. 2) of the display assembly 300 may be higher than the hardness of another portion of the polymer film 420 positioned in the deformable area (e.g., the folding area 233 of FIG. 2) of the display assembly 300.

Referring to FIG. 10A, the polymer film 420 may include a first film area 421 positioned under (−Z) the coating layer 401, a second film area 422 positioned under the first film area 421 and positioned in the flat area (e.g., the first flat display area 231 and/or the second flat display area 232 of FIG. 2) of the display assembly 300, and a third film area 423 positioned under the first film area 421 and positioned in the deformable area (e.g., the folding area 233 of FIG. 2) of the display assembly 300.

According to an embodiment, the third hardness of the third film area 423 may be lower than the second hardness of the second film area 422. The second hardness of the second film area 422 may be lower than the first hardness of the first film area 421. For example, the first hardness range may be 5H to 9H. The range of the second hardness may be 4H to 2H, and the range of the third hardness may be 2H or less. According to an embodiment, the first film area 421 may include polyethylene terephthalate (PET). The second film area 422 may include polymethyl methacrylate (PMMA) and/or polyethylene terephthalate (PET). The third film area 423 may include thermoplastic polyurethane (TPU).

Referring to FIG. 10B, the polymer film 420 may include a fourth film area 424 positioned under (−Z) the coating layer 401, and a fifth film area 425 positioned under the fourth film area 424 and positioned in the deformable area (e.g., the folding area 233 of FIG. 2) of the display assembly 300. For example, at least a portion of the fifth film area 425 may be surrounded by the fourth film area 424.

According to an embodiment, the fifth hardness of the fifth film area 425 may be lower than the fourth hardness of the fourth film area 424. For example, the range of the fourth hardness may be 5H to 9H, and the range of the fifth hardness may be 2H or less. According to an embodiment, the fourth film area 424 may include polyethylene terephthalate (PET). The fifth film area 425 may include thermoplastic polyurethane (TPU).

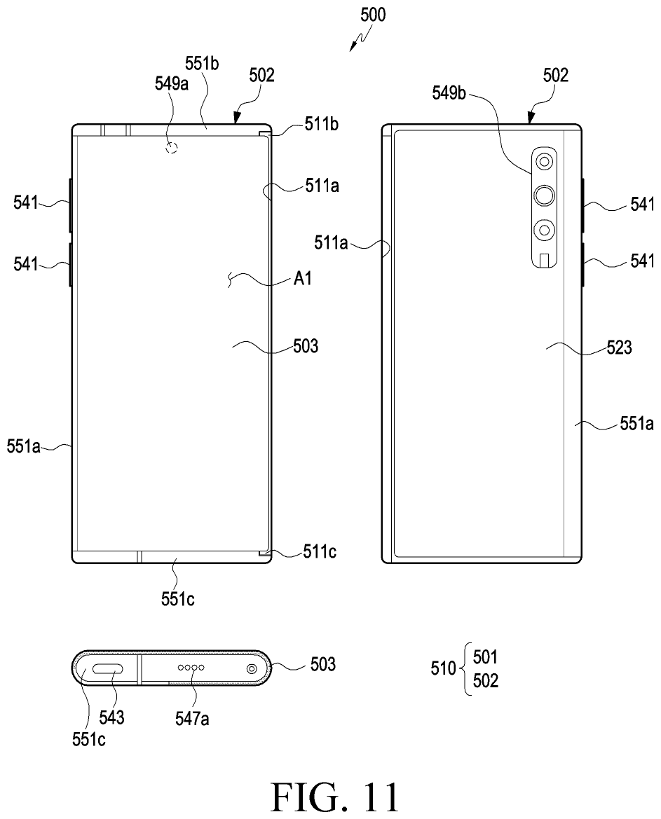

FIG. 11 is a view illustrating an electronic device in a closed state according to an embodiment of the disclosure. FIG. 12 is a view illustrating an electronic device in an open state according to an embodiment of the disclosure. The state illustrated in FIG. 11 may be defined as a state in which the electronic device 101 and/or the housing 510 is closed, and the state illustrated in FIG. 12 may be defined as a state in which the electronic device 101 and/or the housing 510 is open.

Referring to FIGS. 11 and 12, the electronic device 500 may include a housing 510. The housing 510 may include a second housing 502 and a first housing 501 that is movable with respect to the second housing 502. According to an embodiment, the electronic device 500 may be interpreted as having a structure in which the second housing 502 is disposed to be slidable with respect to the first housing 501. According to an embodiment, the first housing 501 may be disposed to perform reciprocating motion by a predetermined distance in a predetermined direction with respect to the second housing 502, for example, a direction indicated by an arrow \textcircled{1}. The configuration of the electronic device 500 of FIGS. 11 and 12 may be identical in whole or part to the configuration of the electronic device 500 of FIG. 1.

According to an embodiment, the first housing 501 may be referred to as a first structure, a slide part, or a slide housing. The second housing 502 may be referred to as, e.g., a second structure, a main part, or a main housing. The second housing 502 may receive at least a portion of the first housing 501 and may guide the slide of the first housing 501. According to an embodiment, the second housing 502 may receive various electrical and electronic components, such as a main circuit board or a battery. According to an embodiment, at least a portion (e.g., the flat display area A1) of the display 503 may be visually exposed to the outside of the housing 501 and 502. According to an embodiment, another portion (e.g., the deformable display area A2) of the display 503 may be received into the inside of the second housing 502 (e.g., a slide-in motion) or be visually exposed to the outside of the second housing 502 (e.g., a slide-out motion) as the first housing 501 moves (e.g., slides) with respect to the second housing 502.

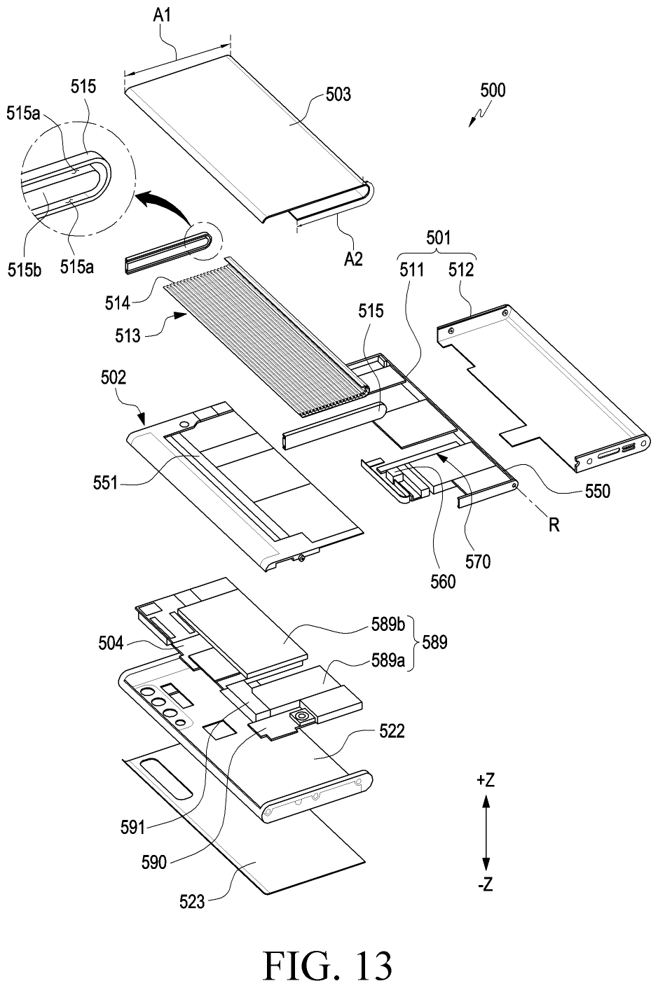

According to various embodiments, the first housing 501 may include first sidewalls 511a, 511b, and 511c for surrounding at least a portion of the display 503 and/or the display supporting member (e.g., the multi-bar structure 513 of FIG. 13). According to an embodiment, the first sidewalls 511a, 511b, and 511c may extend from a first plate (e.g., the first plate 511 of FIG. 13). The first sidewalls 511a, 511b, and 511c may include a 1-2th sidewall 511b, a 1-3h sidewall 511c opposite to the 1-2th sidewall 511b, and a 1-1th sidewall 511a extending from the 1-2th sidewall 511b to the 1-3h sidewall 511c. For example, the 1-2th sidewall 511b may be positioned above the electronic device 500, and the 1-3h sidewall 511c may be positioned under the electronic device 500. According to an embodiment, the 1-1th sidewall 511a may be substantially perpendicular to the 1-2th sidewall 511b and/or the 1-3h sidewall 511c. According to an embodiment, in the closed state (e.g., FIG. 11) of the electronic device 500, the 1-2th sidewall 511b may face the 2-2th sidewall 551b of the second housing 502, and the 1-3h sidewall 511c may face the 2-3th sidewall 551c of the second housing 502. According to an embodiment, the 1-1th sidewall 511a, the 1-2th sidewall 511b, and/or the 1-3h sidewall 511c may be integrally formed with the first plate (e.g., the first plate 511 of FIG. 13) or the slide cover 512. According to another embodiment, the 1-1th sidewall 511a, the 1-2th sidewall 511b, and/or the 1-3h sidewall 511c may be formed as separate housings and may be coupled or assembled.

According to various embodiments, the second housing 502 may include second sidewalls 551a, 521b, and 521c to surround at least a portion of the first housing 501. According to an embodiment, the second sidewalls 551a, 521b, and 521c may extend from a second plate (e.g., the second plate 551 of FIG. 13) and/or a cover member (e.g., the cover member 522 of FIG. 13). According to an embodiment, the second sidewalls 551a, 521b, and 521c may include a 2-2th sidewall 551b, a 2-3th sidewall 551c opposite to the 2-2th sidewall 551b, and a 2-1th sidewall 551a extending from the 2-2th sidewall 551b to the 2-3th sidewall 551c. For example, the 2-2th sidewall 551b may be positioned above the electronic device 500, and the 2-3th sidewall 551c may be positioned under the electronic device 500. According to an embodiment, the 2-1th sidewall 551a may be substantially perpendicular to the 2-2th sidewall 551b and/or the 2-3th sidewall 551c. According to an embodiment, the 2-2th sidewall 551b may face the 1-2th sidewall 511b, and the 2-3th sidewall 551c may face the 1-3th sidewall 511c. For example, in the closed state (e.g., FIG. 11) of the electronic device 500, the 2-2th sidewall 551b may cover at least a portion of the 1-2th sidewall 511b, and the 2-3th sidewall 551c may cover at least a portion of the 1-3h sidewall 511c.

According to various embodiments, the second housing 502 may be formed to be open at one side (e.g., a front face) to receive (or surround) at least a portion of the second housing 501. For example, the first housing 501 may be connected to the second housing 502 while being at least partially surrounded by the 2-1th sidewall 551a, the 2-2th sidewall 551b, and the 2-3th sidewall 551c and may be slid in the direction of arrow \textcircled{1} while being guided by the second housing 502. According to an embodiment, the cover member (e.g., the cover member 522 of FIG. 13), the 2-1th sidewall 551a, the 2-2th sidewall 551b, and/or the 2-3th sidewall 551c may be formed integrally. According to another embodiment, the second cover member 522, the 2-1th sidewall 551a, the 2-2th sidewall 551b, and/or the 2-3th sidewall 551c may be formed as separate housings and be combined or assembled.

According to various embodiments, the second housing 502 may include a rear plate 523. According to an embodiment, the rear plate 523 may form at least a portion of the exterior of the electronic device 500. For example, the rear plate 523 may provide a decorative effect on the exterior of the electronic device 500.

According to various embodiments, the electronic device 500 may include a display 503. The display 503 may be referred to as a flexible display or a rollable display. According to an embodiment, at least a portion of the display 503 (e.g., the deformable display area A2) may slide based on the sliding movement of the first housing 501. According to an embodiment, the display 503 may include, or be disposed adjacent to, a touch detection circuit, a pressure sensor capable of measuring the intensity (pressure) of a touch, and/or a digitizer that detects a magnetic field-type stylus pen. The configuration of the display 503 of FIGS. 11 and 12 may be identical in whole or part to the configuration of the display module 160 of FIG. 1.

According to various embodiments, the display 503 may include a flat display area A1 and a deformable display area A2. According to an embodiment, the flat display area A1 may be an area that is always visible from the outside. According to an embodiment, the flat display area A1 may be interpreted as an area that cannot be positioned inside the housing 501 and 502. According to an embodiment, the deformable display area A2 may extend from the flat display area A1, and the deformable display area A2 may be inserted or received in, or visually exposed to the outside of, the second housing 502 as the first housing 501 slides. According to an embodiment, the flat display area A1 may be seated on a portion (e.g., the first plate 511) of the first housing 501. According to an embodiment, the flat display area A1 may be referred to as a flat area, and the deformable display area A2 may be referred to as a deformable area.

According to various embodiments, the deformable display area A2 may be substantially moved while being guided by the display supporting member (e.g., the multi-bar structure 513 of FIG. 13) mounted in the first housing 501 and may be thus received in, or visually exposed to the outside of, the second housing 502 or a space formed between the first housing 501 and the second housing 502. According to an embodiment, the deformable display area A2 may be moved based on the sliding movement of the first housing 501 in the width direction (e.g., the direction indicated by the arrow \textcircled{1}. For example, at least a portion of the deformable display area A2 may be unfolded or rolled together with the multi-bar structure 513 based on a slide of the first housing 501.

According to various embodiments, when viewed from above the first housing 501, if the first housing 501 moves from the closed state to the open state, the deformable display area A2 may be gradually exposed to the outside of the housing 502 to be substantially coplanar with the flat display area A1. In an embodiment, the deformable display area A2 may be at least partially received in the first housing 501 and/or the second housing 502.

According to various embodiments, the electronic device 500 may include at least one key input device 541, a connector hole 543, audio modules 547a and 547b, or camera modules 549a and 549b. Although not shown, the electronic device 500 may further include an indicator (e.g., a light emitting diode (LED) device) or various sensor modules. The configuration of the audio module 547a and 547b and camera modules 549a and 549b of FIGS. 11 and 12 may be identical in whole or part to the configuration of the audio module 170 and the camera module 180 of FIG. 1.

According to various embodiments, the key input device 541 may be positioned in one area of the second housing 502. Depending on the appearance and the state of use, the electronic device 500 may be designed to omit the illustrated key input device 541 or to include additional key input device(s). According to an embodiment, the electronic device 500 may include a key input device, e.g., a home key button or a touchpad disposed around the home key button. According to another embodiment, at least a portion of the key input device 541 may be disposed on the second housing 502.

According to various embodiments, the key input device 541 may be used as a driving structure for automatically or semi-automatically providing a slide in-out motion of the display 503. For example, when the user presses an open trigger button (e.g., the key input device 541 of FIG. 11) exposed outside the electronic device 500, the display 503 may automatically slide in or out (automatic operation). As another example, when the user slides out the display 503 by pushing the display 203 of the electronic device 500 up to a designated section, for the remaining section, it may be completely slid out by the force of the elastic member mounted in the electronic device 500 (semi-automatic operation). For example, the electronic device 500 may slide out in the closed state (e.g., FIG. 11) and switch to the opened state (e.g., FIG. 12). The slide-in motion of the electronic device 500 may also be performed to correspond to the slide-out motion.

According to various embodiments, the connector hole 543 may be omitted or may receive a connector (e.g., a universal serial bus (USB) connector) for transmitting and receiving power and/or data with an external electronic device. Although not shown, the electronic device 500 may include a plurality of connector holes 543, and some of the plurality of connector holes 543 may function as connector holes for transmitting/receiving audio signals with an external electronic device. In the illustrated embodiment, the connector hole 543 is disposed in the 2-3th sidewall 551c, but the present invention is not limited thereto. The connector hole 543 or a connector hole not shown may be disposed in the 2-1th sidewall 551a or the 2-2th sidewall 551b.

According to various embodiments, the audio modules 547a and 547b may include at least one speaker hole 547a and 547b or at least one microphone hole. At least one of the speaker holes 547a and 547b may be provided as an external speaker hole. At least one of the speaker holes 547a and 547b may be provided as a receiver hole for voice call. The electronic device 500 may include a microphone for obtaining sound. The microphone may obtain external sound of the electronic device 500 through the microphone hole. According to an embodiment, the electronic device 500 may include a plurality of microphones to detect the direction of sound. According to an embodiment, the electronic device 500 may include an audio module in which the speaker holes 547a and 547b and the microphone hole are implemented as one hole or may include a speaker without the speaker hole (e.g., a piezo speaker).

According to various embodiments, the camera modules 549a and 549b may include a first camera module 549a (e.g., front camera) and/or a second camera module 549b (e.g., rear camera). According to an embodiment, the first camera module 549a may include an under display camera (UDC) that has a screen display area (e.g., the flat display area A1) that may not be visually exposed but hidden. The second camera module 549b may capture the subject in a direction opposite to the flat display area A1 of the display 503.

According to various embodiments, an indicator (e.g., an LED device) of the electronic device 500 may be disposed on the first housing 501 and/or the second housing 502, and the indicator may include a light emitting diode to provide state information about the electronic device 500 as a visual signal. The sensor module (e.g., the sensor module 176 of FIG. 1) of the electronic device 500 may produce an electrical signal or data value corresponding to the internal operation state or external environment state of the electronic device 500. The sensor module may include, for example, a proximity sensor, a fingerprint sensor, or a biometric sensor (e.g., an iris/face recognition sensor or a heartrate monitor (HRM) sensor). In another embodiment, the electronic device 500 may include at least one of a gesture sensor, a gyro sensor, an atmospheric pressure sensor, a magnetic sensor, an accelerometer, a grip sensor, a color sensor, an infrared (IR) sensor, a temperature sensor, a humidity sensor, or an illuminance sensor. The configuration of the display 503, audio module 547a and 547b, and camera module 549a and 549b of FIGS. 11A and 11B may be identical in whole or part to the configuration of the display module 160, the audio module 170, and the camera module 180 of FIG. 1.

FIG. 13 is a perspective view illustrating an electronic device according to an embodiment of the disclosure.

Referring to FIG. 13, an electronic device 500 may include a first housing 501, a second housing 502, a display 503, and a multi-bar structure 513. A portion (e.g., the deformable display area A2) of the display 503 may be received in the electronic device 500 while being guided by the multi-bar structure 513. The configuration of the first housing 501, the second housing 502, and the display 503 of FIG. 13 may be identical in whole or part to the configuration of the first housing 501, the second housing 502, and the display 503 of FIGS. 11 and/or 12.

According to various embodiments, the first housing 501 may include a first plate 511 and a slide cover 512. The first plate 511 and the slide cover 512 may linearly reciprocate in one direction (e.g., the direction of arrow η in FIG. 12) while being guided by the second housing 502. According to an embodiment, the first plate 511, along with the slide cover 512, may slide with respect to the second housing 502. For example, at least a portion of the display 503 and/or at least a portion of the multi-bar structure 513 may be disposed between the first plate 511 and the slide cover 512.

According to an embodiment, the first plate 511 may support at least a portion of the display 503. For example, in the closed state (e.g., FIG. 11) of the electronic device 500, the first plate 511 may support at least a portion of the flat display area A1 and, in the open state (e.g., FIG. 12) of the electronic device 500, the first plate 511 may support at least a portion of the flat display area A1 and at least a portion of the deformable display area A2. According to an embodiment, the first plate 511 may include a curved surface 550. At least a portion of the deformable display area A2 of the display 503 may be positioned on the curved surface 550. According to an embodiment, the first plate 511 may be interpreted as a display support bar (DSB) or a display support plate (DSP).

According to an embodiment, the slide cover 512 may protect the display 503 positioned on the first plate 511. For example, the slide cover 512 may surround at least a portion of the display 503. At least a portion of the display 503 may be positioned between the first plate 511 and the slide cover 512. According to an embodiment, the first plate 511 and the slide cover 512 may be formed of a metal material and/or a non-metal (e.g., polymer) material.

According to various embodiments, the first housing 501 may include a guide rail 515 (e.g., a guide structure). According to an embodiment, the guide rail 515 may be connected to the first plate 511 and/or the slide cover 512. For example, the guide rail 515, along with the first plate 511 and the slide cover 512, may slide with respect to the second housing 502.

According to various embodiments, the electronic device 500 may include a multi-bar structure 513. According to an embodiment, the multi-bar structure 513 may support the display 503. For example, the multi-bar structure 513 may be attached to the display 503. According to an embodiment, at least a portion of the display 503 and the multi-bar structure 513 may be positioned between the first plate 511 and the slide cover 512. According to an embodiment, as the first housing 501 slides, the multi-bar structure 513 may move with respect to the second housing 502. In the closed state (e.g., FIG. 11) of the multi-bar structure 513, most of the structure may be received in the second housing 502. According to an embodiment, at least a portion of the multi-bar structure 513 may move corresponding to the curved surface 550 positioned at the edge of the first plate 511.

According to various embodiments, the multi-bar structure 513 may include a plurality of rods 514 (or bars). The plurality of rods 514 may extend in a straight line and be disposed parallel to the rotational axis R formed by the curved surface 550, and the plurality of rods 214 may be arranged along a direction perpendicular to the rotational axis R (e.g., the direction along which the first housing 501 slides).

According to various embodiments, each rod 514 may pivot around another adjacent rod 514 while remaining parallel with the other adjacent rod 514. According to an embodiment, as the first housing 501 slides, the plurality of rods 514 may be arranged to form a curved shape or may be arranged to form a planar shape. For example, as the first housing 501 slides, a portion of the multi-bar structure 513 facing the curved surface 550 may form a curved surface, and another portion of the multi-bar structure 513 that does not face the curved surface 550 may form a flat surface. According to an embodiment, the deformable display area A2 of the display 503 may be mounted or supported on the multi-bar structure 513, and in the open state (e.g., FIG. 12), at least a portion of the deformable display area A2, along with the flat display area A1, may be exposed to the outside of the second housing 502. In the state in which the deformable display area A2 is exposed to the outside of the second housing 502, the multi-bar structure 513 may substantially form a flat surface, thereby supporting or maintaining the deformable display area A2 in the flat state. According to an embodiment, the multi-bar structure 513 may be replaced with a bendable integral supporting member (not shown). According to an embodiment, the multi-bar structure 513 may be interpreted as a display supporting member, a display supporting multi-bar or an articulated hinge structure.

According to various embodiments, the guide rail 515 may guide the movement of the plurality of rods 514. According to an embodiment, the guide rail 515 may include an upper guide rail adjacent to the 1-2th sidewall (e.g., the 1-2th sidewall 511b of FIG. 12) and a lower guide rail adjacent to the 1-3th sidewall (e.g., the 1-3th sidewall 511c of FIG. 12). According to an embodiment, the guide rail 515 may include a groove-shaped rail 515a formed inside the guide rail 515 and a protrusion 515b positioned inside the guide rail. At least a portion of the protrusion 515b may be surrounded by the rail 515a. According to an embodiment, the multi-bar structure 513 may be positioned between the upper guide rail and the lower guide rail and may move while remaining engaged with the upper and lower guide rails. For example, upper and/or lower portions of the plurality of rods 514 may slide along the rail 515a while fitted into the rail 515a.

According to an embodiment, when the electronic device 500 is opened (e.g., a slide-out operation), the size of the area where the display 503 is exposed to the outside may be increased. For example, by driving the driving motor 560 (e.g., driving for sliding out the display) and/or by an external force provided by the user, the first plate 511 connected with the driving motor 560 may be slid out, and the protrusion 515b inside the guide rail 515 may push out the upper and/or lower ends of the plurality of rods 514. Accordingly, the display 503 received between the first plate 511 and the slide cover 512 may be extended to the front.

According to an embodiment, when the electronic device 500 is closed (e.g., a slide-in operation), the size of the area where the display 503 is exposed to the outside may be reduced. For example, by driving the driving motor 560 (e.g., driving for sliding in the display) and/or by an external force provided by the user, the first plate 511 where the motor is disposed may be slid in, and the outer portion (e.g., a portion other than the protrusion 515b) of the guide rail 515 may push out the upper and/or lower ends of the plurality of rods 514. Accordingly, the extended display 503 may be received between the first plate 511 and the slide cover 512.

According to various embodiments, the second housing 502 may include a second plate 551, a cover member 522, and a rear plate 523. According to an embodiment, the second plate 551 may support at least a portion (e.g., the flat display area A1) of the display 503. The first plate 551 may be disposed between the display 503 and the circuit board 504. According to an embodiment, the cover member 522 may receive components (e.g., the battery 589 (e.g., the battery 189 of FIG. 1) and the circuit board 504) of the electronic device 500 and may protect the components of the electronic device 500. According to an embodiment, the cover member 522 may be referred to as a book cover.

According to various embodiments, a plurality of circuit boards may be received in the second housing 502. A processor, memory, and/or interface may be mounted on the circuit board 504 which is the main board. The processor may include one or more of, e.g., a central processing unit, an application processor, a graphic processing device, an image signal processing, a sensor hub processor, or a communication processor. According to various embodiments, the circuit board 504 may include a flexible printed circuit board type radio frequency cable (FRC). For example, the circuit board 504 may be disposed in the cover member 522 and may be electrically connected with an antenna module (e.g., the antenna module 197 of FIG. 1) and a communication module (e.g., the communication module 190 of FIG. 1).

According to an embodiment, the memory may include, e.g., a volatile or non-volatile memory.

According to an embodiment, the interface may include, e.g., a high definition multimedia interface (HDMI), a universal serial bus (USB) interface, a secure digital (SD) card interface, and/or an audio interface. The interface may electrically or physically connect, e.g., the electronic device 500 with an external electronic device and may include a USB connector, an SD card/multimedia card (MMC) connector, or an audio connector.

According to various embodiments, the electronic device 500 may further include a separate sub circuit board 590 spaced apart from the circuit board 540 in the second housing 502. The sub circuit board 590 may be electrically connected with the circuit board 540 through the flexible circuit board 591. The sub circuit board 590 may be electrically connected with electrical components disposed in an end of the electronic device 500, such as the battery 589 or a speaker and/or a sim socket, and may transfer signals and power.

According to an embodiment, the battery 589 may be a device for supplying power to at least one component of the electronic device 500. The battery 189 may include, e.g., a primary cell which is not rechargeable, a secondary cell which is rechargeable, or a fuel cell. At least a portion of the battery 589 may be disposed on substantially the same plane as the circuit board 504. The battery 589 may be integrally or detachably disposed inside the electronic device 500.

According to various embodiments, the battery 589 may be formed as a single embedded battery or may include a plurality of removable batteries (e.g., the first battery 589a and the second battery 589b). According to an embodiment, when the embedded battery is positioned on the first plate 511, the embedded battery may move as the first plate 511 slides. According to an embodiment, when the embedded battery is positioned on the second plate 551, the embedded battery may be fixedly disposed on the second plate 551, regardless of the slide of the first plate 511. As another example, when the first battery 589a of the removable batteries is positioned on the first plate 511, and the second battery 589b of the removable batteries is fixedly positioned on the second plate 551, only the first battery 589a may move as the first plate 511 slides.

According to various embodiments, the rear plate 523 may substantially form at least a portion of the exterior of the second housing 502 or the electronic device 500. For example, the rear plate 523 may be coupled to the outer surface of the cover member 522. According to an embodiment, the rear plate 523 may be integrally formed with the cover member 522. According to an embodiment, the rear plate 523 may provide a decorative effect on the exterior of the electronic device 500. The second plate 551 and the cover member 522 may be formed of at least one of a metal or a polymer, and the rear plate 523 may be formed of at least one of metal, glass, synthetic resin or ceramic. According to an embodiment, the second plate 551, the cover member 522 and/or the rear plate 523 may be formed of a material that transmits light at least partially (e.g., the auxiliary display area). For example, in a state in which a portion of the display 503 (e.g., the deformable display area A2) is received in the electronic device 500, the electronic device 500 may output visual information using the deformable display area A2. The auxiliary display area may be a portion of the second plate 551, the cover member 522, and/or the rear plate 523 in which the display 503 received in the second housing 502 is positioned.

According to an embodiment, the electronic device 500 may include a driving motor 560 and a gear assembly 570 for sliding the electronic device 500. The driving motor 560 may include a motor core for generating power. The gear assembly 570 may move and/or rotate by receiving at least a portion of the driving force generated by the driving motor 560. The first housing 501 may receive at least a portion of the driving force generated by the driving motor 560 through the gear assembly 570 and may be moved relative to the second housing 502. According to an embodiment, the gear assembly 570 may include a gear (e.g., a pinion) connected to the driving motor 260 and a rack configured to be engaged with the gear. The gear and the rack may be connected to different housings.

The electronic device 500 disclosed in FIGS. 11 to 13 has a rollable or slidable appearance but the present invention is not limited thereto. According to an embodiment (not shown), at least a portion of the illustrated electronic device may be rolled up in a scroll shape.

Referring to FIGS. 11 to 13, when viewed from the front of the electronic device 500, the display 503 may extend to the right of the electronic device 500. However, the structure of the electronic device 500 is not limited thereto. For example, according to an embodiment, the display 503 may extend to the left of the electronic device 500. According to another embodiment, the display 503 may expand in the length direction of the electronic device 500.

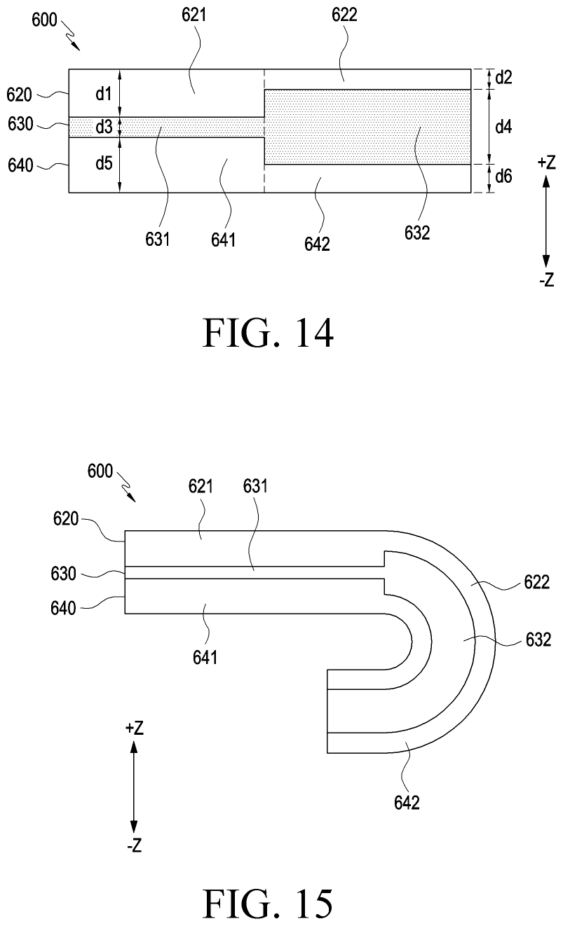

FIG. 14 is a cross-sectional view illustrating a display assembly in a closed state according to an embodiment of the disclosure. FIG. 15 is a cross-sectional view illustrating a display assembly in an open state according to an embodiment of the disclosure.

Referring to FIGS. 14 and 15, the display assembly 600 may include a polymer film 620, an adhesive layer 630, and a glass 640. The configuration of the polymer film 620, the adhesive layer 630, and the glass 640 of FIG. 14 and/or FIG. 15 may be identical in whole or part to the configuration of the polymer film 320, the adhesive layer 330, and the glass 340 of FIG. 5, and the configuration of the display assembly 600 of FIG. 14 and/or FIG. 15 may be identical in whole or part to the configuration of the display 503 of FIG. 13.

According to various embodiments, the polymer film 620 may be formed to be bent based on deformation of the display assembly 600 including the rollable display. For example, the polymer film 620 may have a different thickness for each portion. According to an embodiment, the polymer film 620 may include a first area 621 positioned in the flat display area A1 and a second area 622 positioned in the deformable display area A2. The second thickness d2 of the second area 622 may be smaller than the first thickness d1 of the first area 621. For example, the second thickness d2 may be 10% to 90% of the first thickness d1. According to an embodiment, the first thickness d1 may be about 100 μm, and the second thickness d2 may be about 50 μm. According to an embodiment, the first thickness d1 may range from about 30 μm to 150 μm. According to an embodiment, as the second thickness d2 of the second area 622 is formed to be smaller than the first thickness d1 of the first area 621, bending (e.g., rolling) of the display assembly 600 may be enhanced. For example, the repulsive force of the second area 622 may be less than the repulsive force of the first area 621, and the repulsive force of the deformable area (e.g., the deformable display area A2 of FIG. 12) in which the second area 622 is positioned may be less than the repulsive force of the flat area (e.g., the flat display area A1 of FIG. 12) in which the first area 621 is positioned.

According to various embodiments, the glass 640 may be formed to be bent based on deformation of the display assembly 600. For example, the glass 640 may have a different thickness for each portion. According to an embodiment, the glass 640 may include a fifth area 641 positioned in a flat area (e.g., the flat display area A1 of FIG. 12) of a display (e.g., the display 603 of FIG. 13) and a sixth area 642 positioned in a deformable area (e.g., the deformable display area A2 of FIG. 12) of the display 603. A sixth thickness d6 of the sixth area 642 may be smaller than a fifth thickness d5 of the fifth area 641. For example, the sixth thickness d6 may be 10% to 90% of the fifth thickness d5. According to an embodiment, the glass 640 may be designed to have various thicknesses. For example, the fifth thickness d5 may be about 50 μm, and the sixth thickness d6 may be about 30 μm. As another example, the fifth thickness d5 may be about 80 μm, and the sixth thickness d6 may be about 40 μm. The structure in which the thickness of the glass 640 is changed is optional. For example, the glass 640 may have a substantially uniform thickness.

According to various embodiments, the adhesive layer 630 may be formed to correspond to the shape of the polymer film 620 and/or the glass 640. For example, the adhesive layer 630 may have a different thickness for each portion. According to an embodiment, the adhesive layer 630 may include a third area 631 positioned in a flat area (e.g., the flat display area A1 of FIG. 12) of a display (e.g., the display 503 of FIG. 13) and a fourth area 632 positioned in a deformable area (e.g., the deformable display area A2 of FIG. 12) of the display 503. A fourth thickness d4 of the sixth area 632 may be larger than a third thickness d3 of the third area 631. According to an embodiment, the sum of the thicknesses of the polymer film 620, the sum of the thicknesses of the adhesive layer 630, and the sum of the thicknesses of the glass 640 may be substantially uniform. For example, the sum of the first thickness d1 of the polymer film 620, the third thickness d3 of the adhesive layer 630, and the fifth thickness d5 of the glass 640 may be substantially the same as the sum of the second thickness d2 of the polymer film 620, the fourth thickness d4 of the adhesive layer 630, and the sixth thickness d6 of the glass 640.

According to various embodiments of the disclosure, an electronic device (e.g., the electronic device 200 of FIG. 2) may include a housing (e.g., the housing 202 of FIG. 2) including a first housing (e.g., the first housing 210 of FIG. 2) and a second housing (e.g., the second housing 220 of FIG. 2) connected to be movable with respect to the first housing, and a display assembly (e.g., the display assembly 300 of FIG. 5 and/or the display assembly 600 of FIG. 14) including a flat area (e.g., the first flat display area 231 of FIG. 2, the second flat display area 232, and/or the flat display area A1 of FIG. 12) connected to the housing and a deformable area (e.g., the folding area 233 of FIG. 2 and/or the deformable display area A2 of FIG. 12) extending from the flat area and configured to be at least partially folded or rolled based on a relative movement of the housing. The display assembly may include a protective layer (e.g., the protective layer 310 of FIG. 5) for protecting the display assembly from an external impact of the electronic device, and including a polymer film (e.g., the polymer film 320 of FIG. 5), a display panel (e.g., the display panel 350 of FIG. 7) configured to output an image, a glass (e.g., the glass 340 of FIG. 5) disposed on the display panel, and an adhesive layer (e.g., the adhesive layer 330 of FIG. 5) disposed between the glass and the polymer film. The polymer film may include a first area (e.g., the first area 321 of FIG. 5) positioned in the flat area and having a first thickness (e.g., the first thickness d1 of FIG. 5), and a second area (e.g., the second area 322 of FIG. 5) positioned in the deformable area and having a second thickness (e.g., the second thickness d2 of FIG. 5) smaller than the first thickness. The adhesive layer may include a third area (e.g., the third area 331 of FIG. 5) positioned in the flat area and having a third thickness (e.g., the third thickness d3 of FIG. 5), and a fourth area (e.g., the third area 331 of FIG. 5) positioned in the deformable area and having a fourth thickness (e.g., the fourth thickness d4 of FIG. 5) larger than the third thickness.

According to various embodiments, the glass may include a fifth area (e.g., the fifth area 341 of FIG. 7) positioned in the flat area and having a fifth thickness (e.g., the fifth thickness d5 of FIG. 7), and a sixth area (e.g., the sixth area 342 of FIG. 7) positioned in the deformable area and having a sixth thickness (e.g., the sixth thickness d6 of FIG. 7) smaller than the fifth thickness.

According to various embodiments, the third area may be positioned between the first area and the fifth area, and the fourth area may be positioned between the second area and the sixth area.

According to various embodiments, the protective layer may include a coating layer (e.g., the coating layer 311 of FIG. 7) disposed on the polymer film.

According to various embodiments, the adhesive layer may include a second adhesive layer (e.g., the second adhesive layer 3302 of FIG. 9A and/or FIG. 9B) disposed on the glass and a first adhesive layer (e.g., the first adhesive layer 3301 of FIG. 9A and/or FIG. 9B) spaced apart from the second adhesive layer. The polymer film may include a second polymer film (e.g., the second polymer film 3202 of FIG. 9A and/or FIG. 9B) disposed between the first adhesive layer and the second adhesive layer and a first polymer film (e.g., the first polymer film of FIG. 9A and/or FIG. 9B) disposed on the second adhesive layer.

According to various embodiments, the second polymer film may include a 1-2th area (e.g., the 1-2th area 3202a of FIG. 9A) positioned in the flat area and a 2-2th area (e.g., the 2-2th area 3202b of FIG. 9A) positioned in the deformable area and thinner than the 1-2th area. The first adhesive layer may include a 3-1th area (e.g., the 3-1th area 3301a of FIG. 9A) positioned between the first polymer film and the 1-2th area and a 4-1th area (e.g., the 4-1th area 3301b of FIG. 9A) positioned between the first polymer film and the 2-2th area and thicker than the 3-1th area. The second adhesive layer may include a 3-2th area (e.g., the 3-2th area 3302a of FIG. 9A) positioned between the glass and the 1-2th area and a 4-2th area (e.g., the 4-2th area 3302b of FIG. 9A) positioned between the first polymer film and the 2-2th area and thicker than the 3-2th area.

According to various embodiments, the first polymer film may include a 1-1th area (e.g., the 1-1th area 3201a of FIG. 9B) positioned in the flat area and a 2-1th area (e.g., the 2-1th area 3201b of FIG. 9B) positioned in the deformable area and thinner than the 1-1th area. The second polymer film may include a 1-2th area (e.g., the 1-2th area 3202a of FIG. 9B) positioned in the flat area and a 2-2th area (e.g., the 2-2th area 3202b of FIG. 9B) positioned in the deformable area and thinner than the 1-2th area. The first adhesive layer may include a 3-1th area (e.g., the 3-1th area 3301a of FIG. 9B) positioned between the 1-1th area and the 1-2th area and a 4-1th area (e.g., the 4-1th area 3301a of FIG. 9B) positioned between the first polymer film and the 2-2th area and thicker than the 3-1th area.

According to various embodiments, the adhesive layer may include at least one of an optically clear resin (OCR) or an optically clear adhesive (OCA).

According to various embodiments, the second thickness may be 10% to 90% of the first thickness.

According to various embodiments, a sum of thicknesses of the protective layer, the adhesive layer, and the glass may be substantially uniform.

According to various embodiments, the first area may include a first surface (e.g., the first surface 330a of FIG. 8A) facing the adhesive layer. The second area may include a second surface (e.g., the second surface 330b of FIG. 8A) facing the adhesive layer and a third surface (e.g., the third surface 330c of FIG. 8A) extending from the first surface to the second surface. A first angle (e.g., the first angle x1 of FIG. 8A) between the first surface and the third surface may range from 10 degrees to 30 degrees.

According to various embodiments, the polymer film may include a curved portion (e.g., the curved portion 301 of FIG. 5) positioned between the first area and the second area and having a curvature of 0.05R or more.

According to various embodiments, the electronic device may further include a hinge (e.g., the hinge structure 280 of FIG. 4) connected to the first housing and the second housing. The flat area may include a first flat display area (e.g., the first flat display area 231 of FIG. 2) positioned in the first housing and a second flat display area (e.g., the second flat display area 232 of FIG. 2) positioned in the second housing. The deformable area may include a folding area (e.g., the folding area 233 of FIG. 2) positioned between the first flat display area and the second flat display area.

According to various embodiments, the display assembly may include a multi-bar structure (e.g., the multi-bar structure 513 of FIG. 13) supporting the display panel. The deformable area may extend from the flat area, and may be at least partially connected to the multi-bar structure.

According to various embodiments, the electronic device may further include a driving motor (e.g., the driving motor 260 of FIG. 13) disposed in the housing and configured to generate a driving force for sliding the housing, and a gear assembly (e.g., the gear assembly 270 of FIG. 13) configured to move the first housing with respect to the second housing based on the driving force.

According to various embodiments, the polymer film may include at least one of polyethylene terephthalate (PET), polycarbonate (PC), polymethyl methacrylate (PMMA), and/or thermoplastic polyurethane (TPU).

According to various embodiments of the disclosure, a display assembly (e.g., the display assembly 300 of FIG. 5 and/or the display assembly 600 of FIG. 14) may include a protective layer (e.g., the protective layer 310 of FIG. 5) including a polymer film (e.g., the polymer film 320 of FIG. 5), a display panel (e.g., the display panel 350 of FIG. 7) configured to output an image, a glass (e.g., the glass 340 of FIG. 5) disposed on the display panel, and an adhesive layer (e.g., the adhesive layer 330 of FIG. 5) disposed between the glass and the polymer film. The polymer film may include a first area (e.g., the first area 321 of FIG. 5) positioned in a flat area of the display assembly and having a first thickness (e.g., the first thickness d1 of FIG. 5), and a second area (e.g., the second area 322 of FIG. 5) positioned in the deformable area and having a second thickness (e.g., the second thickness d2 of FIG. 5) smaller than the first thickness. The adhesive layer may include a third area (e.g., the third area 331 of FIG. 5) positioned in the flat area of the display assembly and having a third thickness (e.g., the third thickness d3 of FIG. 5), and a fourth area (e.g., the fourth thickness d4 of FIG. 5) positioned in the deformable area and having a fourth thickness (e.g., the fourth thickness d4 of FIG. 5) larger than the third thickness.

According to various embodiments of the disclosure, an electronic device (e.g., the electronic device 200 of FIG. 2) may include a housing (e.g., the housing 202 of FIG. 2) including a first housing (e.g., the first housing 210 of FIG. 2) and a second housing (e.g., the second housing 220 of FIG. 2) connected to be movable with respect to the first housing, and a display assembly (e.g., the display assembly 300 of FIG. 5 and/or the display assembly 600 of FIG. 14) including a flat area (e.g., the first flat display area 231 of FIG. 2, the second flat display area 232, and/or the flat display area A1 of FIG. 12) connected to the housing and a deformable area (e.g., the folding area 233 of FIG. 2 and/or the deformable display area A2 of FIG. 12) extending from the flat area and configured to be at least partially folded or rolled based on a relative movement of the housing. The display assembly may include a protective layer (e.g., the protective layer 310 of FIG. 5) for protecting the display assembly from an external impact of the electronic device, and including a polymer film (e.g., the polymer film 320 of FIG. 5), a display panel (e.g., the display panel 350 of FIG. 7) configured to output an image, a glass (e.g., the glass 340 of FIG. 5) disposed on the display panel, and an adhesive layer (e.g., the adhesive layer 330 of FIG. 5) disposed between the glass and the polymer film. The display may include a protective layer (e.g., the protective layer 401 of FIG. 10A) for protecting the display assembly from an external impact of the electronic device, and including a polymer film (e.g., the polymer film 420 of FIG. 10A), a display panel (e.g., the display panel 350 of FIG. 7) configured to output an image, a glass (e.g., the glass 340 of FIG. 7) disposed on the display panel, and an adhesive layer (e.g., the adhesive layer 330 of FIG. 7) disposed between the glass and the polymer film. The polymer film may include a first film area (e.g., the first film area 421 of FIG. 10A) facing outward of the display assembly, a second film area (e.g., the second film area 422 of FIG. 10A) positioned in the flat area and having a second hardness, and a third film area (e.g., the third film area 423 of FIG. 10A) positioned in the deformable area and having a third hardness lower than the second hardness.

According to various embodiments of the disclosure, there may be provided a display assembly including a polymer film in which the thickness of the deformable area is smaller than the flat area and an adhesive layer in which the thickness of the deformable area is larger than the thickness of the flat area. Due to the structure of the polymer film and the adhesive layer, the repulsive force and driving resistance of the display may be reduced while maintaining the durability of the foldable display or the rollable display. The above-described embodiments are merely specific examples to describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. An electronic device, comprising:
a housing comprising a first housing, and a second housing connected to the first housing and configured to be movable with respect to the first housing; and
a display assembly comprising a flat area connected to the housing, and a deformable area extending from the flat area and configured to be at least partially folded or rolled based on a movement relative to the housing,
wherein the display assembly comprises:
a protective layer for protecting the display assembly from an external impact to the electronic device, the protective layer comprising a polymer film;
a display panel configured to output an image;
a glass disposed on the display panel; and
an adhesive layer disposed between the glass and the polymer film,
wherein a first area of the polymer film positioned in the flat area has a first thickness, and a second area of the polymer film positioned in the deformable area has a second thickness smaller than the first thickness, and
wherein a third area of the adhesive layer positioned in the flat area has a third thickness, and a fourth area of the adhesive layer positioned in the deformable area has a fourth thickness greater than the third thickness.

2. The electronic device of claim 1, wherein a fifth area of the glass positioned in the flat area has a fifth thickness, and a sixth area of the glass positioned in the deformable area has a sixth thickness smaller than the fifth thickness.

3. The electronic device of claim 1, wherein the protective layer further comprises a coating layer disposed on the polymer film.

4. The electronic device of claim 1, wherein the adhesive layer comprises a second adhesive layer disposed on the glass, and a first adhesive layer spaced apart from the second adhesive layer, and
wherein the polymer film comprises a second polymer film disposed between the first adhesive layer and the second adhesive layer, and a first polymer film disposed on the first adhesive layer.

5. The electronic device of claim 4, wherein the second polymer film comprises a 1-2th area positioned in the flat area, and a 2-2th area positioned in the deformable area and thinner than the 1-2th area,
wherein the first adhesive layer comprises a 3-1th area positioned between the first polymer film and the 1-2th area, and a 4-1th area positioned between the first polymer film and the 2-2th area and thicker than the 3-1th area, and
wherein the second adhesive layer comprises a 3-2th area positioned between the glass and the 1-2th area, and a 4-2th area positioned between the first polymer film and the 2-2th area and thicker than the 3-2th area.

6. The electronic device of claim 4, wherein the first polymer film comprises a 1-1th area positioned in the flat area, and a 2-1th area positioned in the deformable area and thinner than the 1-1th area,
wherein the second polymer film comprises a 1-2th area positioned in the flat area, and a 2-2th area positioned in the deformable area and thinner than the 1-2th area, and
wherein the first adhesive layer comprises a 3-1th area positioned between the 1-1th area and the 1-2th area, and a 4-1th area positioned between the first polymer film and the 2-2th area and thicker than the 3-1th area.

7. The electronic device of claim 1, wherein the adhesive layer comprises at least one of an optically clear resin (OCR) or an optically clear adhesive (OCA).

8. The electronic device of claim 1, wherein the second thickness is 10% to 90% of the first thickness.

9. The electronic device of claim 1, wherein a sum of a thickness of the protective layer, a thickness of the adhesive layer, and a thickness of the glass is substantially uniform among the flat area and the deformable area.

10. The electronic device of claim 1, wherein the first area comprises a first surface facing the adhesive layer,
wherein the second area comprises a second surface facing the adhesive layer, and a third surface extending from the first surface to the second surface, and
wherein a first angle between the first surface and the third surface is at least 10 degrees and less than 30 degrees.

11. The electronic device of claim 1, wherein the polymer film comprises a curved portion positioned between the first area and the second area and having a radial curvature of at least 0.05R.

12. The electronic device of claim 1, further comprising a hinge connected to the first housing and the second housing,
wherein the flat area comprises a first flat display area positioned in the first housing and a second flat display area positioned in the second housing, and
wherein the deformable area comprises a folding area positioned between the first flat display area and the second flat display area.

13. The electronic device of claim 1, wherein the display assembly further comprises a multi-bar structure supporting the display panel, and
wherein the deformable area extends from the flat area, and is at least partially connected to the multi-bar structure.

14. The electronic device of claim 13, further comprising:
a driving motor disposed in the housing and configured to generate a driving force for a slide movement of the housing; and
a gear assembly configured to move the first housing with respect to the second housing based on the driving force.

15. An electronic device, comprising:
a housing comprising a first housing, and a second housing connected to the first housing and configured to be movable with respect to the first housing; and
a display assembly comprising a flat area connected to the first housing, and a deformable area extending from the flat area and configured to be at least partially folded or rolled based on a movement relative to the housing,
wherein the display assembly comprises:
a protective layer for protecting the display assembly from an external impact of the electronic device and comprising a polymer film;
a display panel configured to output an image;
a glass disposed on the display panel; and
an adhesive layer disposed between the glass and the polymer film,
wherein the polymer film comprises a first film area facing outward from the display assembly, a second film area positioned in the flat area and having a first hardness, and a third film area positioned in the deformable area and having a second hardness lower than the first hardness.
